(19) United States
(12) Patent Application Publication
(10) Pub. No.: US 2011/0162701 A1
(43) Pub. Date: Jul. 7, 2011

(54) Photovoltaic Cells

(76) Inventors: Claudio Truzzi, Incourt (BE); Steve Lerner, Carlisle, MA (US)

(21) Appl. No.: 12/651,475

(22) Filed: Jan. 3, 2010

(51) Int. Cl. H01L 31/02; H01L 31/18

(52) U.S. Cl. 136/256; 438/98; 257/E31.113

(57) ABSTRACT

A photovoltaic cell is provided herein. The photovoltaic cell includes a substrate whereby at least one interconnects may be formed over the substrate to facilitate energy conversion of the photovoltaic cell. In this embodiment, a conformal layer may be deposited over the interconnects, the conformal layer having a thickness of up to about 100 nm, and whereby the conformal layer is designed to permit external radiation to pass through to the interconnects so as to enhance the efficiency of energy conversion by at least about 25% as measured at standard test condition. In another embodiment, the interconnects of the photovoltaic cell may have tapered profile as to facilitate collection of diffused external radiation. In some instances, the tapered profile may facilitate in diverting the diffused external radiation to the interconnects for enhancing energy conversion of the photovoltaic cell. A method for method of manufacturing a photovoltaic cell is also provided.

### FIELD OF THE INVENTION

The present invention relates to photovoltaic cells and methods of fabricating the same. More particularly, the present invention relates to photovoltaic cells having a solution-activated substrate for electroless metal deposition such that the deposited metal is substantially thin, conformal and transparent.

### BACKGROUND

Solar cells may be used for powering objects including the likes of calculators and satellites. In some instances, solar cells may also be referred to as photovoltaic cells or modules (group of cells electrically connected and packaged in one frame). Photovoltaic cells are capable of converting sunlight directly into electricity for use in a variety of applications.

Photovoltaic cells may be made of semiconductor materials such as silicon. Functionally, when light strikes a photovoltaic cell, certain portions of the light may be absorbed within the semiconductor material. This means that energy of the absorbed light may be transferred to the semiconductor material. This energy is capable of knocking loose electrons within the semiconductor material allowing them to flow freely whereby the free flowing electrons are capable of generating current. Using electric fields within the photovoltaic cell and metal contacts on the top and bottom of the photovoltaic cell, current may be drawn off to be used externally. The current, together with the photovoltaic cell's voltage (which may be a result of its built-in electric fields), defines the power (or wattage) that a solar cell can produce.

### SUMMARY OF THE INVENTION

The present invention provides, in an embodiment, a photovoltaic cell. The photovoltaic cell includes a substrate whereby at least one interconnects may be formed over the substrate to facilitate energy conversion of the photovoltaic cell. In this embodiment, a conformal layer may be deposited over the interconnects, the conformal layer having a thickness of up to about 100 nm, and whereby the conformal layer is designed to permit external radiation to pass through to the interconnects so as to enhance the efficiency of energy conversion by at least about 25% as measured at standard test condition. In another embodiment, the interconnects of the photovoltaic cell may have tapered profile as to facilitate collection of diffused external radiation. In some instances, the tapered profile may facilitate in diverting the diffused external radiation to the interconnects for enhancing energy conversion of the photovoltaic cell.

The present invention provides, in another embodiment, a photovoltaic cell.

The photovoltaic cell includes a substrate conditioned with a solution to permit the surface of the substrate to receive a conformal metal coating by electroless deposition. In this embodiment, a nickel-boron layer may be deposited on the substrate by electroless deposition, the nickel-boron layer being substantially conformal and having a thickness of up to about 100 nm, so as to enhance efficiency of energy conversion of external radiation directed through the layer and to the substrate. In another embodiment, the nickel-boron layer may be capable of enhancing efficiency of energy conversion by at least about 25% as measured at standard test condition. In another embodiment, interconnects may be formed over the substrate of the photovoltaic cell to facilitate energy conversion of the photovoltaic cell, whereby the interconnects have a tapered profile as to facilitate collection of diffused external radiation. In some instances, the tapered profile may facilitate in diverting the diffused external radiation to the interconnects for enhancing energy conversion of the photovoltaic cell.

The present invention provides, in one embodiment, a method of manufacturing a photovoltaic cell. The method includes providing a solution designed to condition a substrate surface to receive a conformal metal coating by electroless deposition, immersing a substrate into the solution, and depositing on to the surface of the substrate a substantially conformal first conductive material. In another embodiment, the first conductive material is substantially transparent, and has a thickness of up to about 100 nm. In another embodiment, the first conductive material is nickel-boron. In another aspect, the first conductive material enhances the efficiency of energy conversion by at least about 25% as measured at standard test condition. In another aspect, the method includes depositing a second conductive material on to first conductive material. In some aspect, the second conductive material is at least one of copper, gold, aluminum or alloys thereof. In another embodiment, interconnects may be formed over the substrate of the photovoltaic cell to facilitate energy conversion of the photovoltaic cell, whereby the interconnects have a tapered profile as to facilitate collection of diffused external radiation. In some instances, the tapered profile may facilitate in diverting the diffused external radiation to the interconnects for enhancing energy conversion of the photovoltaic cell.

A plurality of photovoltaic cells disclosed above may be coupled to form a solar module. In one embodiment, an integrated circuit incorporating the photovoltaic cell discussed above may be used in connection with one of a powering device, a multi-touch screen, a flat panel display, a touch screen, a mobile device, and a medical device. In another embodiment, an integrated circuit incorporating the photovoltaic cell discussed above may be used in connection with supplying electrical power to signages, street lights or similar devices. In yet another embodiment, an integrated circuit incorporating the photovoltaic cell discussed above may be used in connection as a bridge or supplement to traditional power source for consumer electronics products.

### BRIEF DESCRIPTION OF THE DRAWINGS

FIG. 1 illustrates a cross-sectional view of a photovoltaic cell in accordance with one embodiment of the present invention;

FIGS. 2A-2H illustrate a process flow for producing the photovoltaic cell of FIG. 1 in accordance with one embodiment of the present invention;

FIGS. 3A-3B illustrate portions of a process flow for producing a variation of the photovoltaic cell of FIG. 1 in accordance with one embodiment of the present invention;

FIGS. 4A-4C illustrate portions of a process flow for producing a variation of the photovoltaic cell of FIG. 1 in accordance with another embodiment of the present invention;

FIGS. 5A-5B illustrate the energy conversion efficiencies between photovoltaic cells with vertical profile versus tapered profile; and

FIGS. 6A-6J illustrate a process flow for producing a photovoltaic cell in accordance with another embodiment of the present invention.

### DETAILED DESCRIPTION OF SPECIFIC EMBODIMENTS

### Photovoltaic Cell

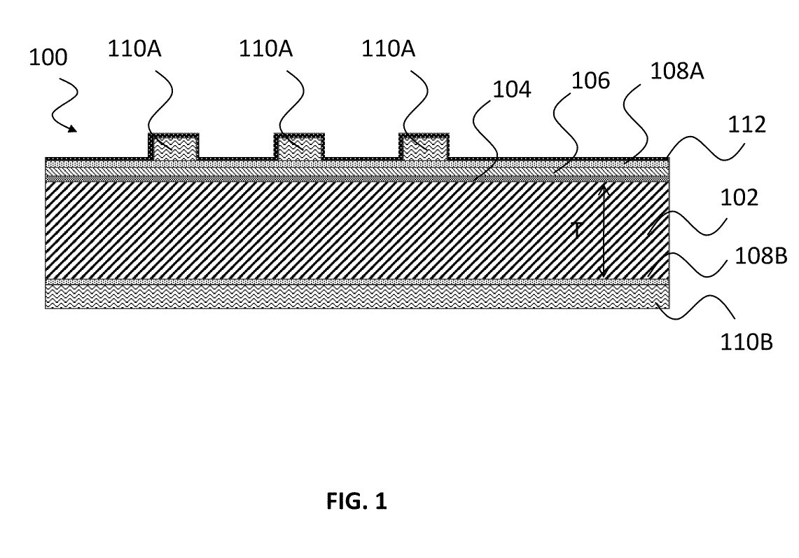

Reference is now made to FIG. 1 illustrating a cross-sectional view of a photovoltaic cell 100 according to one embodiment of the present disclosure. The photovoltaic cell 100 includes a substrate 102 designed to serve as a base or supporting material to which additional layers or materials may be applied, formed or deposited thereon. Substrate 102, in an embodiment, can be made from p-type silicon, n-type silicon, or similar materials, and, if desired, can be provided with substantially uniform thickness. In an embodiment, the substrate 102 may be a semiconductor material made from, for example, silicon (Si), gallium arsenide (GaAs), indium phosphide (InP), glass and sapphire, among others

Photovoltaic cell 100 may also include a p-n junction 104 and an n+ diffused layer 106 deposited over the substrate 102. The p-n junction 104 and the n+ diffused layer 106 may facilitate the formation of an array of active and/or passive elements over or about the substrate 102. The array of active and/or passive elements may be collectively referred to as interconnects, which may include patterned electrical integrated circuits. In some instances, the interconnects may be capable of performing at least one complete electronic circuit function (e.g., execute a command) In other instances, the interconnects may facilitate the flow of electrons (e.g., current generation). As such, directly and/or indirectly, the interconnects may be responsible for determining the conversion efficiency of a photovoltaic cell 100.

As used herein, conversion efficiency is a measure of the effectiveness of the energy conversion by describing the ratio between the energy supplied and the energy input. For example, a photovoltaic cell 100 having a conversion efficiency of about 35% means that about 35% of the incoming solar energy can be converted into electrical energy, with the interconnects being one of the primary drivers in the conversion process. The energy being converted may be used by electrical and/or mechanical devices in real-time (e.g., instantaneously), be stored for future use (e.g., battery), or be incorporated in a hybrid system where portions of the converted energy may be used while portions may be stored.

Photovoltaic cell 100 may further include a substantially conformal layer 108 such as conformal layer 108A over an upper surface and conformal layer 108B over a bottom surface of the photovoltaic cell 100, respectively, from the perspective of FIG. 1. In an embodiment, conformal layers 108A and 108B may be minimally resistive and relatively conductive. Specifically, the upper conformal layer 108A may be designed to permit external radiation to pass through to the underlying layers (e.g., interconnects) including the likes of the n+ diffused layer 106 and the p-n junction 104, to name a few. In doing so, the conformal layer 108A can enhance the efficiency of energy conversion by at least about 10% (and in some instances up to about 25%) as measured at standard test condition.

As used herein, conformal layer means a layer that is capable of being substantially uniformly deposited throughout an exterior perimeter of the underlying layer, while having a substantially uniform thickness throughout. For example, a conformal layer 108 deposited over an underlying material (e.g., substrate 102, p-n junction 104, n+ diffused layer 106) may have substantially similar film thickness at the top surface, the bottom surface, and the sidewalls of the underlying material. In one embodiment, conformal layer 108 may be able to maintain substantially uniform film thickness throughout the perimeter of the underlying layer regardless of any features (e.g., linewidths, vias, interconnects) that may be present on the surface of the underlying layer(s). In other words, regardless of the interconnect features, conformal layer 108 may still be able to provide substantially uniform thickness throughout the photovoltaic cell 100.

In addition, as used herein, external radiation includes the likes of alpha radiation, beta radiation, gamma radiation and solar energy, among others. In some instances, the external radiation may be natural occurring or artificially generated source (e.g., light from a powered source). In order to permit external radiation to pass therethrough, the conformal layer 108A may be substantially transparent. In one embodiment, the conformal layer 108A may be sufficiently transparent to permit the external radiation to penetrate through the thickness of the conformal layer 108A and into any of the underlying layers including through the interconnects and into the substrate 102.

Furthermore, as used herein, standard test condition means testing a solar cell at about 1000 W/m² (watts per square meter) of light input with the solar cell being at a temperature of about 25° C. and an air mass of about 1.5. The standard test condition may also be applied to solar modules, photovoltaic cells, photovoltaic modules, among other devices and apparatuses.

Still referring to FIG. 1, photovoltaic cell 100 can include metal contacts 110A formed about a front side of the cell 100. In an embodiment, metal contacts 110A can be configured to define patterns and/or layouts in accordance with a desired circuit layout and/or electrical design. In an embodiment, the metal contacts 110A may be capable of functioning as electrodes of the photovoltaic cell 100 and may be capable of facilitating the flow of electrons. Photovoltaic cell 100, from the perspective of FIG. 1, can also include back side metal 110B deposited substantially about the back side of the photovoltaic cell 100. The back side metal 110B, in an embodiment, can be designed to provide a substantially continuous, electrical contact (e.g., an electrode) about the back side of the photovoltaic cell 100.

In accordance with one embodiment of the present invention, a protective covering layer 112 may be deposited over the metal contacts 110A, and conformal layer 108A. Should it be desired, covering layer 112 may also be deposited over side walls of substrate 102, so as to cover the sidewalls of the p-n junction 104 and the n+ diffused layer 106. However, depending on the application, covering layer 112 need not be deposited over the sidewalls of substrate 102. In certain embodiments, the covering layer 112 may be used to protect the sidewalls of the back side conformal layer 108B and/or the back side metal 110B.

With the presence of the various layers on substrate 102, it should be appreciated that substrate 102 may need to be substantially thin (e.g., minimize thickness (T) of the substrate 102) to reduce the distance over which electron flow may occur. In particular, a shorter distance may result in lower recombination of carriers and increased conversion efficiency within the photovoltaic cell 100. For example, the ability of the photovoltaic cell 100 to convert solar energy to electrical energy may be in the range of from about 20% to about 23% when the substrate 102 is maintained at a thickness (T) of up to about 300 microns. In another example, the ability of the photovoltaic cell 100 to convert solar energy to electrical energy may increase to at least about 22.5% when the thickness (T) of the substrate 102 is in the range of from about 10 microns to about 300 microns.

In some instances, shallower junctions (e.g., thinner p-n junction 104) may be used to increase the capture of higher energy blue region of the light spectrum in order to enhance conversion efficiency of the photovoltaic cell 100. In such instances, photovoltaic cells 100 may be provided with conversion efficiency in the range of from about 16% to about 18%, and more particularly, from about 16.8% to about 17.6%.

To further enhance conversion efficiency by the photovoltaic cell 100 of the present invention, conformal layer 108 may be made, in an embodiment, from nickel-boron. It has been observed that when utilizing a substantially thin and transparent nickel-boron conformal layer an improved conversion efficiency by the photovoltaic cell 100 of from about 25% to about 40% can result. In particular, the utilization of such a nickel-boron layer can, in embodiment, minimize resistance of current flowing through substrate 102 with minimal disruption (and in some instances, no disruption) to the electrical current flow. In some aspects, the improvement in conversion efficiency may be at least about 5%, or at least about 10%, or at least about 15%, or at least about 20%, or at least about 25%, or at least about 30%, or at least about 35%, or at least about 40%.

In one aspect of the present invention, the nickel-boron conformal layer 108 may be deposited using suitable electroless metal deposition methods known in the art. In another aspect, an activation step may precede the deposition step, and can involve immersing the silicon substrate having an oxide layer thereon within an activation solution, followed by plating the treated substrate with suitable electroless metal plating techniques known in the art. In some instances, the substrate may have more layers formed thereon in addition to the oxide layer.

Methods, processes and techniques of fabricating photovoltaic cells having the features, functionalities and attributes described above are discussed below.

### Fabrication of Photovoltaic Cell

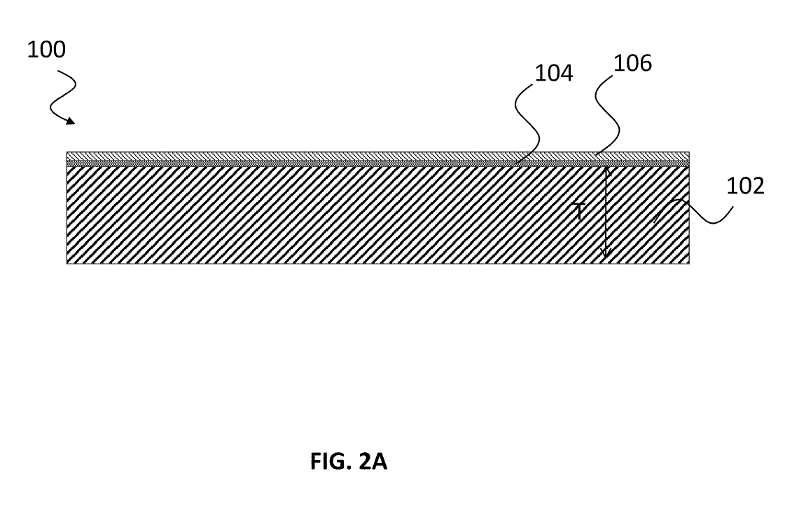

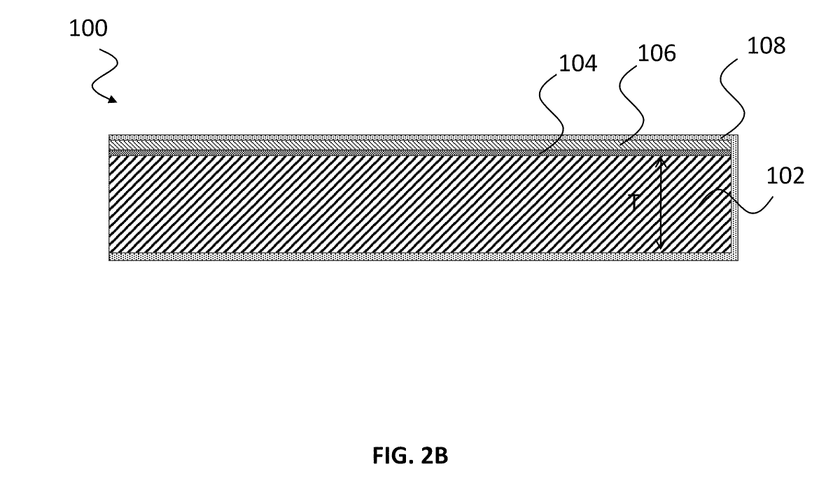

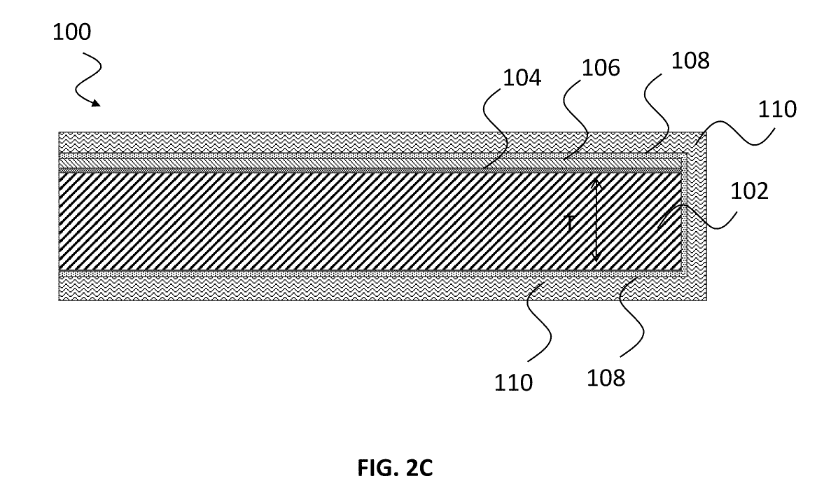

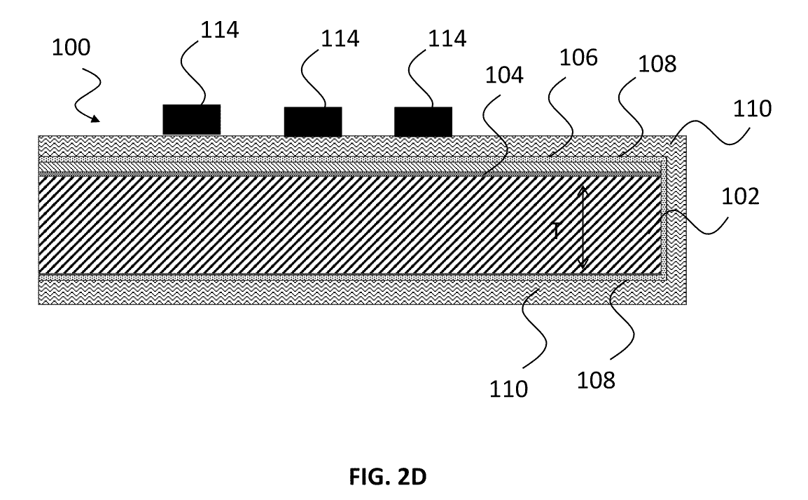

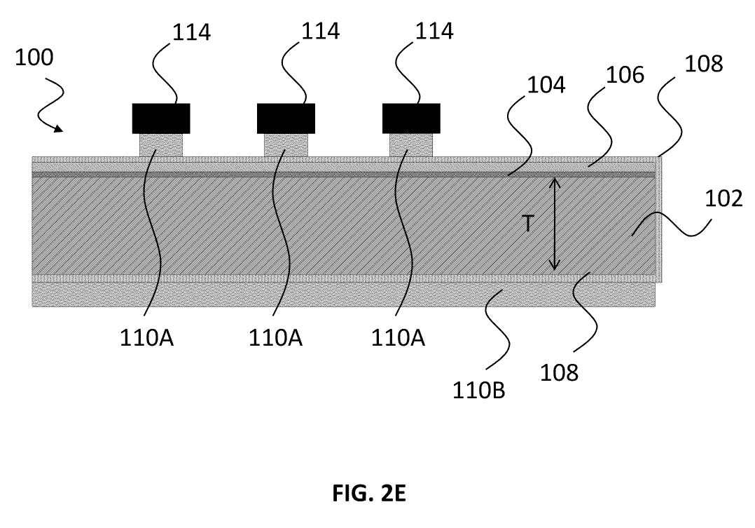

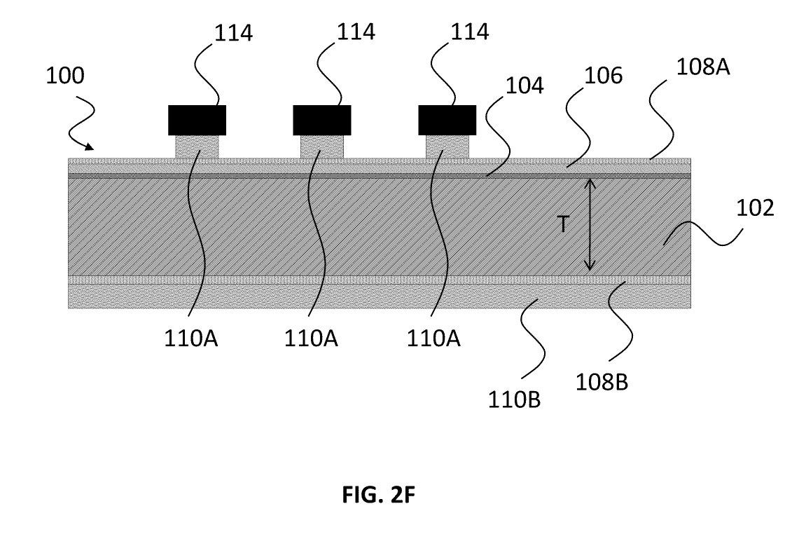

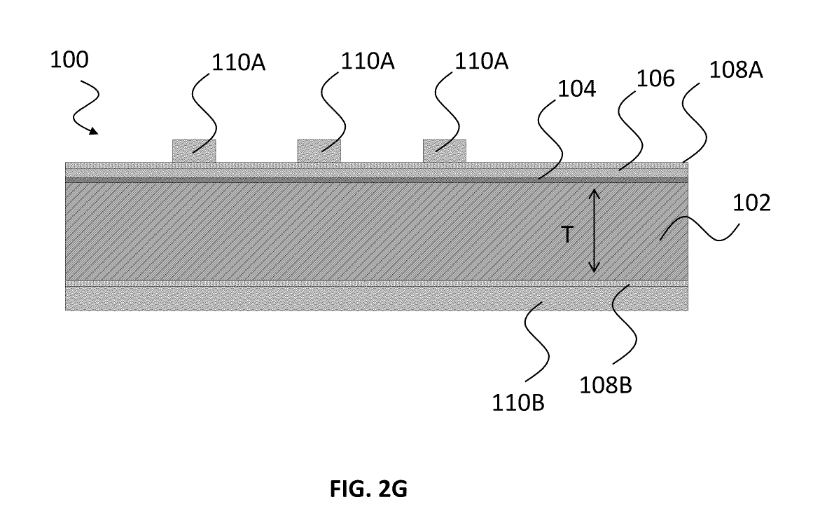

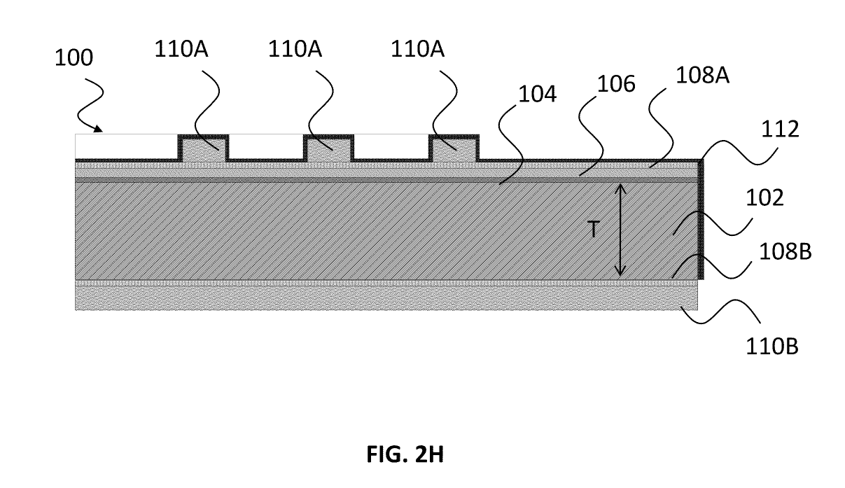

Reference is now made to FIGS. 2A-2H illustrating a process flow for fabricating the photovoltaic cell 100 of FIG. 1 according to one embodiment of the present disclosure.

FIG. 2A shows a photovoltaic cell 100 including a substrate 102, which may be part of a wafer from which dies are cut, and may serve as grounding for the electrical circuits being formed thereon. The substrate 102 may be a semiconductor material made from, for example, silicon (Si), gallium arsenide (GaAs), indium phosphide (InP), glass and sapphire, among others.

In some embodiments, the thickness (T) of the substrate 102 may be up to about 700 microns, or up to about 600 microns, or up to about 500 microns, or up to about 400 microns, or up to about 300 microns, or up to about 200 microns, or up to about 100 microns, or up to about 50 microns. In some aspects of the present disclosure, the thickness (T) of the substrate 102 may be in the range of from about 500 microns to about 700 microns, or from about 100 microns to about 700 microns, or from about 100 microns to about 500 microns, or from about 100 microns to about 300 microns, or from about 10 microns to about 300 microns, or from about 10 microns to about 200 microns, or from about 10 microns to about 100 microns, or from about 10 microns to about 50 microns, or from about 40 microns to about 350 microns, or from about 40 microns to about 250 microns, or from about 40 microns to about 200 microns, or from about 40 microns to about 150 microns, or from about 40 microns to about 100 microns, or from about 40 microns to about 50 microns. Of course, the substrate 102 can be provided with different varying thicknesses as desired.

A p-n junction 104 and an n+ diffused layer 106 may be formed (e.g., positioned) over the substrate 102 by, for example, suitable diffusion processes or other semiconductor processes known in the art. In one example, the p-n junction 104 may be diffused to a thickness of about 0.3 micron. In some instances, the thickness of the p-n junction 104 can be in the range of from about 0.1 micron to about 2 microns. Similarly, the n+ diffused layer 106 may have comparable thickness. In other embodiments, other types of layers may be formed over the substrate 102 including gate oxide layers, poly-silicon layers, silicon dioxide layers, among others.

FIG. 2B shows a conformal layer 108 being formed around the periphery of the photovoltaic cell 100 once the p-n junction 104 and n+ diffused layer 106 have been deposited on the photovoltaic cell 100. In this instance, the conformal layer 108 may be formed around the exterior surfaces of the various layers and materials discussed above. For example, the conformal layer 108 may surround the top side, bottom side and the sidewalls of the substrate 102, the p-n junction 104 and the n+ diffused layer 106.

In one instance, a front side conformal layer 108A may be deposited over the top side of the n+ diffused layer 106 while a back side conformal layer 108B may be deposited on the back side of the substrate 102. The deposition of the conformal layers 108A, 108B may be carried out using a single processing step. In other words, the back side conformal layer 108B may be formed over the back side of the substrate 102 at substantially the same time (e.g., simultaneously, concomitantly) as the front side conformal layer 108A is being deposited over the n+ diffused layer 106, and vice versa. In some instances, the deposition of the conformal layers 108A, 108B can employ two or more processing steps.

In one embodiment, the conformal layer 108 may have a thickness of up to about 100 nm. In some embodiments, the conformal layer 108 may have a thickness of up to about 90 nm, or up to about 80 nm, or up to about 70 nm, or up to about 60 nm, or up to about 50 nm, or up to about 40 nm, or up to about 30 nm, or up to about 20 nm, or up to about 10 nm, or up to about 5 nm. In other embodiments, the conformal layer 108 may have a thickness of at least about 5 nm, or at least about 10 nm, or at least about 15 nm, or at least about 25 nm, or at least about 35 nm, or at least about 45 nm, or at least about 55 nm, or at least about 65 nm, or at least about 75 nm, or at least about 85 nm, or at least about 95 nm. In some aspects of the present disclosure, the conformal layer 108 may have thicknesses in the range of from about 5 nm to about 100 nm, or from about 5 nm to about 50 nm, or from about 5 nm to about 25 nm, or from about 5 nm to about 20 nm, or from about 5 nm to about 10 nm, or from about 10 nm to about 90 nm, or from about 10 nm to about 50 nm, or from about 10 nm to about 25 nm, or from about 10 nm to about 20 nm.

In some embodiments, the conformal layer 108 may be up to 99% transparent, or up to 95% transparent, or up to 90% transparent, or up to 80% transparent, or up to 70% transparent, or up to 60% transparent, or up to 50% transparent. In other embodiments, the conformal layer 108 may be at least about 55% transparent, or at least about 65% transparent, or at least about 75% transparent, or at least about 85% transparent, or at least about 98% transparent. In some instances, the transparency of the conformal layer 108 may be in the range of from about 50% to about 99%, or from about 50% to about 95%, or from about 50% to about 90%, or from about 50% to about 80%, or from about 60% to about 99%, or from about 60% to about 95%, or from about 60% to about 90%, or from about 60% to about 80%, or from about 70% to about 99%, or from about 70% to about 95%, or from about 70% to about 90%, or from about 70% to about 80%, or from about 80% to about 99%, or from about 80% to about 95%, or from about 80% to about 90%.

As noted above, to enhance conversion efficiency of the photovoltaic cell 100 of the present invention, the conformal layer 108 may be made from a nickel-based material, or a cobalt-based material, or alloys and/or combinations thereof. In some embodiments, the conformal layer 108 maybe made from a titanium-based material, tantalum-based material, nitride-based material, silicon-nitride based material, titanium-nitride based material, tantalum-nitride based material, titanium-tantalum based material, or alloys thereof, among others.

In one embodiment, the nickel-boron alloy may be deposited by suitable electroless metal deposition techniques known in the art. The presence of the nickel-boron alloy layer may help to minimize (and in some instances, prevent) metal (e.g., metal contact) from leaching into the interconnects. In other words, the nickel-boron alloy may be capable of functioning as a barrier layer by preventing the migration or diffusion of copper or other conductive material from penetrating through to the substrate 102, the p-n junction 104 and/or the n+ diffused layer 106.

In one embodiment, a method of preparing a nickel-based material as the conformal layer 108 includes:
a) Bringing a semiconductor substrate into contact with a liquid solution comprising:
   (1) A protic solvent;
   (2) At least one diazonium salt;
   (3) At least one monomer that is chain-polymerizable and soluble in the protic solvent;
   (4) At least one acid in a sufficient quantity to stabilize the diazonium salt by adjusting the pH of the solution to a value less than 7, preferably less than 2.5; and
(b) Polarizing the surface according to a potentio- or galvano-pulsed mode for a duration sufficient to form a film having a thickness of at least 80 nanometers, and in some instances between 100 and 500 nanometers.

The protic solvent used in the aforementioned method may be chosen from the group consisting of water (e.g., deionized or distilled water); hydroxylated solvents (e.g., alcohols having 1 to 4 carbon atoms); carboxylic acids having 2 to 4 carbon atoms (e.g., formic acid, acetic acid, and mixtures thereof).

Thus, according to a particular characteristic, the diazonium salt may be an aryldiazonium salt chosen from the compounds of the following formula (I):

R—N2+,A- (I), in which:
(1) A represents a monovalent anion,
(2) R represents an aryl group.

Examples of an aryl group R include unsubstituted, mono- or polysubstituted aromatic or heteroaromatic carbon structures, consisting of one or more aromatic or heteroaromatic rings, each comprising 3 to 8 atoms, the heteroatom(s) being chosen from N, O, S, or P; and optional substituent(s) including electron-attracting groups such as NO2, COH, ketones, CN, CO2H, NH2, esters and the halogens.

Examples of R groups include nitrophenyl and phenyl groups.

Among the compounds of formula (I) above, A may be chosen from inorganic anions such as halides like I—, Br— and Cl—, haloboranes such as tetrafluoroborane, and organic anions such as alcoholates, carboxylates, perchlorates and sulphates.

In some embodiments, the diazonium salt of the aforementioned formula (I) may be chosen from phenyldiazonium tetrafluoroborate, 4-nitrophenyldiazonium tetrafluoroborate, 4 bromophenyldiazonium tetrafluoroborate, 2-methyl-4-chlorophenyldiazonium chloride, 4-benzoylbenzenediazonium tetrafluoroborate, 4 cyano┌phenyldiazonium tetrafluoroborate, 4-carboxyphenyldiazonium tetrafluoroborate, 4-acetamidophenyldiazonium tetrafluoroborate, 4-phenylacetic acid diazonium tetrafluoroborate, 2-methyl-4-[(2-methylphenyl)-diazenyl]benzenediazonium sulphate, 9,10-dioxo-9,10-dihydro-1-anthracenediazonium chloride, 4-nitrophthalenediazonium tetrafluoroborate, and napthalenediazonium tetrafluoroborate, 4-amino┌phenyldiazonium chloride.

In some instances, the diazonium salt may be chosen from phenyldiazonium tetrafluoroborate and 4-nitrophenyldiazonium tetrafluoroborate.

The diazonium salt may be generally present within the liquid electrografting solution in a quantity between 10−3 and 10−1M, or between 5×10−3 and 3×10−2M.

Generally speaking, an electrografting solution contains at least one monomer that is chain-polymerizable and soluble in the protic solvent.

“Soluble in a protic solvent” is here understood to denote any monomer or mix of monomers whose solubility in the protic solvent is at least 0.5M.

In some embodiments, the monomers may be chosen from vinyl monomers soluble in the protic solvent and satisfying the following general formula (II):

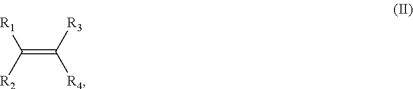

in which identical or different groups R1 to R4 represent a monovalent non-metal atom such as a halogen atom or a hydrogen atom, or a saturated or unsaturated chemical group such as a C1-C6 alkyl or aryl, a —COOR5 group in which R5 represents a hydrogen atom or a C1-C6 alkyl, nitrile, carbonyl, amine or amide group.

In some instances, water-soluble monomers may be used. Such monomers may be chosen from ethylenic monomers comprising pyridine groups such as 4-vinylpyridine or 2-vinylpyridine, or from ethylenic monomers comprising carboxylic groups such as acrylic acid, methacrylic acid, itaconic acid, maleic acid, fumaric acid and their sodium, potassium, ammonium or amine salts, amides of these carboxylic acids and in particular acrylamide and methacrylamide along with their N-substituted derivatives, their esters such as 2-hydroxyethyl methacrylate, glycidyl methacrylate, dimethylamino- or diethylamino(ethyl or propyl)(meth)acrylate and their salts, quaternized derivatives of these cationic esters such as, for example, acryloxyethyl trimethylammonium chloride, 2-acrylamido-2-methylpropane sulphonic acid (AMPS), vinylsulphonic acid, vinylphosphoric acid, vinyllactic acid and their salts, acrylonitrile, N-vinylpyrrolidone, vinyl acetate, N-vinylimidazoline and its derivatives, N vinylimidazole and derivatives of the diallylammonium type such as dimethyldiallylammonium chloride, dimethyldiallylammonium bromide and diethyldiallylammonium chloride.

The quantitative composition of the liquid electrografting solution may vary within broad limits.

Generally speaking, this solution may include:
(a) At least 0.3M of polymerizable monomer(s),
(b) At least 5×10⁻³ M of diazonium salt(s), the molar ratio of the polymerizable monomer(s) to the diazonium salt(s) being between 10 and 300.

As previously mentioned, the use of an electrografting protocol in pulsed mode constitutes another aspect of the present disclosure, to the extent that this particular protocol makes it possible, completely unexpectedly and in contrast to a cyclic voltammetry electrografting protocol, to obtain a continuous and uniform film with a growth kinetics compatible with industrial constraints.

Generally speaking, the polarization of the surface to be covered by the film may be produced in a pulsed mode, each cycle of which is characterized by:

(a) A total period P of between 10 ms and 2 s, or in some instances of around 0.6 s;

(b) A polarization time Ton of between 0.01 and 1 s, or in some instances around 0.36 s, during which a potential difference or a current may be applied to the surface of the substrate; and

(c) An idle period with zero potential or current of a duration of between 0.01 and 1 s, or in some instances around 0.24 s.

In some instances, the aforementioned barrier layer may itself be produced by a wet deposition method, preferably in a liquid medium of protic nature.

The method of preparing an electrically insulating film which has just been described may be also be useful in the preparation of through-vias (e.g., 3D integrated circuits) for constituting the internal electrically insulating layer designed to be coated with the barrier layer serving to prevent copper migration or diffusion. In some aspects of the present disclosure, the barrier layer may serve to prevent copper migration or diffusion and may include a nickel- or cobalt-based metal film.

In some embodiments, methods of preparing a conformal layer 108 by coating a semiconductor substrate 102 with a protic media including those disclosed in U.S. patent application Ser. No. 12/495,137 filed Jun. 30, 2009, which claims priority to French Patent Application No. 08-54442 filed Jul. 1, 2008, each of which is hereby incorporated herein by reference in its entirety for all purposes.

In another aspect of the present disclosure, a method of preparing a nickel-based material as the conformal layer 108 includes initially activating a surface (e.g., oxidized surface) of a silicon substrate 102 by immersing within a solution, followed by subsequently coating the surface with a metal layer electroless metal deposition technique. In this instance, the solution may be characterized in that it contains:
(A) An activator consisting of one or more palladium complexes selected from the group consisting of:
   (1) Palladium complexes having the formula (I)

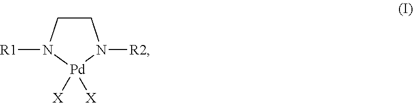

where:
(a) R1 and R2 are identical and are H, CH2CH2NH2, CH2CH2OH; or R1 is H and R2 is CH2CH2NH2; or R1 is CH2CH2NH2 and R2 is CH2CH2NHCH2CH2NH2; or R1 is H and R2 is CH2CH2NHCH2CH2NHCH2CH2NH2; and
(b) X is a ligand selected from the group consisting of Cl—, Br—, I—, H2O, NO3-, CH3SO3-, CF3SO3-, CH3-Ph-SO3-, and CH3COO—;
(II) Palladium complexes having the formula (IIa) or (IIb)

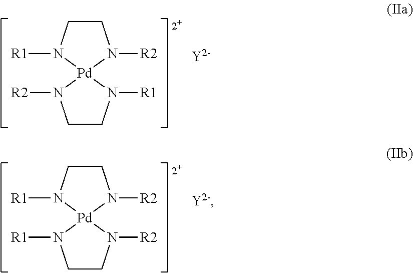

where:
   (a) R1 and R2 are as defined above; and
   (b) Y is a counter-ion comprising two negative charges consisting of:
      (i) Either two monoanions selected from the group consisting of Cl—, PF6-, BF4-, NO3-, CH3SO3-, CF3SO3-, CH3C6H4SO3-, and CH3COO—;
      (ii) Or a dianion, preferably SO42-;
(B) A bifunctional organic binder consisting of one or more organosilane compounds having the general formula:

{NH2-(L)}3-n-Si(OR)n (V), where:
(1) L is a spacing arm selected from the group consisting of CH2, CH2CH2, CH2CH2CH2- and CH2CH2NHCH2CH2;
(2) R is a group selected from the group consisting of CH3, CH3CH2, CH3CH2CH2, (CH3)2CH; and
(3) n is an integer equal to 1, 2 or 3.
(C) A solvent system consisting of one or more solvents suitable for solubilising the activator and the organosilane solvent.

In accordance with another embodiment with the present invention, a bifunctional organic binder consisting of one or more organosilane compounds can have the general formula:

{X-(L)}₃₋ₙ-Si(OR)ₙ (Va)

where:
X is a functional group selected from the group consisting of thiol, pyridyl, epoxy(oxacyclopropanyl), glycidyl, primary amine, chlore and capable to react with palladium compounds of formula I:
L is a spacing arm selected from the group consisting of CH₂; CH₂CH₂; CH₂CH₂CH₂—; CH₂CH₂CH₂CH₂—; CH₂CH₂NHCH₂CH_{2;} CH₂CH₂CH₂NHCH₂CH_{2;} CH₂CH₂CH₂NHCH₂CH₂NHCH₂CH_{2;} CH₂CH₂CH₂NHCH₂CH₂CH₂CH₂CH₂CH_{2;} Ph; Ph-CH₂; et CH₂CH₂-Ph-CH₂; (Ph being a phényl)
R is a group selected from the group consisting of CH₃, CH₃CH₂, CH₃CH₂CH₂, (CH₃)₂CH ; et
n is an integer equal to 1, 2 or 3;
   or the general formula:

(OR)₃Si-(L)-Si(OR)₃ (Vb)

where:
L is a spacing arm selected from the group consisting of CH₂CH₂CH₂NHCH₂CH₂NHCH₂CH₂CH₂ et CH₂CH₂CH₂—S—S—CH₂CH₂CH₂
R is a group selected from the group consisting of CH₃, CH₃CH₂, CH₃CH₂CH₂, (CH₃)₂CH.

In the following description, compounds having the formula (IIa) and (IIb) may be designated collectively by the name “compounds having the formula (II)”.

According to another feature of the present disclosure, this solution may be free of water or comprises water in a concentration lower than 0.5%, or lower than 0.2%, or lower than 0.1% by volume. This limited quantity of water, combined with the complexed form of the activator, may prevent any inactivation of the solution over time and therefore allows its use on an industrial scale.

According to another particular feature of the disclosure, this solution comprises:
(A) The aforementioned activator in a concentration of 10⁻⁶ M to 10⁻² M, or from 10⁻⁵ M to 10⁻³ M, or from 5×10⁻⁵ M to 5×10⁻⁴ M;
(B) The aforementioned binder in a concentration of 10⁻⁵ M to 10⁻¹ M, or from 10⁻⁴ M to 10⁻² M, or from 5×10⁻⁴ M to 5×10⁻³ M.

In one embodiment, the activator of the solution according to the disclosure consists of one or more palladium complexes having the formulas (I) and (II) defined above.

Complexes having formula (I) can be prepared by reacting a palladium salt having formula (III) with a nitrogenated bidentate ligand having the formula (IV) by the following reaction scheme:

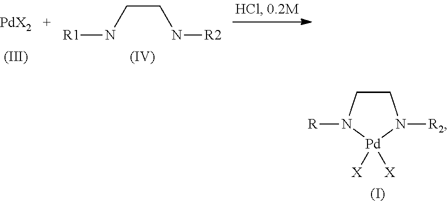

where X, R1 and R2 are similar to those discussed above.

In another embodiment, a palladium salt having the formula (III) is dissolved in an aqueous 0.2 M hydrochloric acid solution at a temperature between 40° C. and 80° C., or about 60° C., for a period of 10 to 20 minutes, or about 20 minutes, to obtain the soluble complex having the formula H2PdCl4.

At the end of the reaction, an equivalent of a nitrogenated bidentate ligand having the formula (IV) may be added to the reaction medium which may be maintained at a temperature between 40 and 80° C., or about 60° C., for a period of 1 to 3 hours, or about 2 hours, to yield the complex having the formula (I). The addition of the ligand may cause a change in colour of the reaction medium.

The solvent may subsequently be evaporated and the solid residue may be treated by recrystallization in a solvent such as ethanol for example.

Preferably, the starting palladium compound may be palladium chloride PdCl2.

Alternatively, the palladium salt having formula (III) may be replaced by a palladium salt having the formula [PdX4]2-, such as K2PdCl4, Li2PdCl4, Na2PdCl4 or (NH4)2PdCl4.

Examples of amine derivatives having the formula (IV) suitable for use in the context of the present disclosure include the following compounds:
(1) Diethylenetriamine (compound having formula (IV) where R1 is a hydrogen atom and R2 is a CH2CH2NH2 group); and
(2) N,N′-Bis(2-hydroxyethyl)ethylenediamine (compound having formula (IV) where R1 and R2 are identical and are CH2CH2OH).

In one embodiment, the amine compound is diethylenetriamine.

Complexes having the formula (II) can be prepared similarly to the preparation of complexes having formula (I) by the following reaction scheme:

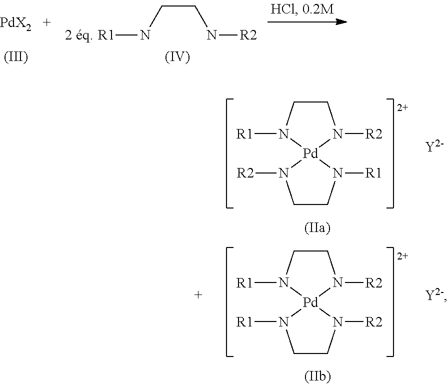

where X, R1 and R2 are similar to those discussed above.

More precisely, a soluble complex is formed having the formula H2PdCl4 in a manner identical to that described above.

At the end of the reaction, two equivalents of the nitrogenated bidentate ligand having formula (IV) are added to the reaction medium which is maintained at a temperature between 60° C. and 80° C. or a period of 8 to 15 hours, or about 12 hours, to yield the complexes having a formula (IIa) and (IIb).

Alternatively, the complexes having formula (II) can be prepared from complexes having formula (I) by adding an equivalent of the nitrogenated bidentate ligand in an appropriate solvent and by maintaining the reaction medium at a temperature between 60 and 80° C., or about 70° C., for a period of 8 to 15 hours, or about 12 hours. In these two cases, the reaction can be facilitated by adding a silver salt to the reaction medium.

The reaction scheme given above shows that the reaction leads to two cis and trans complexes, which are the only complexes formed in the case in which R1 is H and R2 is CH2CH2NH2. Statistical mixtures of several complexes can be obtained in the case in which R1 and R2 are both free radicals having a molecular weight equal to or higher than that of the CH2CH2NH2 group. It has been shown that such mixtures are usable on the industrial scale and need not necessarily be purified to yield the desired result.

The bifunctional organic binder, which constitutes one of the essential components of the solution, consists of one or more compounds having formula (V) defined above. These compounds comprise at least one functional group of the alkoxysilane type suitable for forming a chemical bond with the oxidized surface of the substrate and at least one amine functional group suitable for forming a chemical bond with the palladium complex having formula (I) or (II) defined above.

These compounds provide good adhesion between the successive layers of a substrate having a surface formed of an oxide, in particular when this surface is subsequently covered with a metal layer, in particular of NiB forming a copper diffusion barrier, which is itself covered with a copper seed layer.

Compounds of formula (Va) or (Vb) are, for example, can be selected from the following compounds:

(3-Aminopropyl)triéthoxysilane;

(3-Aminopropyl)triméthoxysilane;

m-Aminophényltriméthoxysilane;

p-Aminophényltriméthoxysilane;

p,m-Aminophényltriméthoxysilane;

4-Aminobutyltriéthoxysilane;

m,p(Aminoéthylaminométhyl)phénéthyltriméthoxysilane;

N-(2-Aminoéthyl)-3-aminopropyltriéthoxysilane;

N-(2-Aminoéthyl)-3-aminopropyltriméthoxysilane;

2-(4-Pyridyléthyl)triéthoxysilane;

Bis(3-triméthoxysilylpropyl)éthylenediamine;

(3-Triméthoxysilylpropyl)diéthylènetriamine;

N-(3-Triméthoxysilyléthyl)éthylènediamine;

N-(6-Aminohexyl)aminopropyltriméthoxysilane;

(3-Glycidoxypropyl)triméthoxysilane;

(3-Glycidoxypropyl)triéthoxysilane;

5,6-Epoxyhexyltriéthoxysilane;

(3-Mercaptopropyl)triméthoxysilane;

(3-Mercaptopropyl)triéthoxysilane;

Bis[3-(triéthoxysilyl)propyl]disulfure;

3-Chloropropyltriméthoxysilane;

3-Chloropropyltriéthoxysilane;

(p-Chlorométhyl)phényltriméthoxysilane;

m,p((Chlorométhyl)phényléthyl)triméthoxysilane.

In accordance with one embodiment, organosilane compounds suitable for use in the context of the present invention can be made of:
Compounds having formula (Va) where:

X is NH₂ and

L is CH₂CH₂CH₂— and R is CH₃ (compound named (3-aminopropyl)-triméthoxy-silane or APTMS);

or L is CH₂CH₂CH₂— and R is CH₃CH₂ (compound named (3-aminopropyl)-triéthoxy-silane or APTES);

or L is CH₂CH₂NHCH₂CH₂ and R is CH₃ (compound named [3-(2-aminoéthyl)aminopropyl]triméthoxy-silane or DATMS or DAMO);

X is SH; L is CH₂CH₂CH₂— and R is CH₂-CH₃ (compound named (3-Mercaptopropyl)triméthoxysilane or MPTES);

or X is C6H5N; L is CH₂CH₂— and R is CH₂—CH₃ (compound named 2-(4-Pyridyléthyl)triéthoxysilane or PETES);

or X is CHCH2O; L is CH₂CH₂CH₂ and R is CH₃ (compound named (3-Glycidoxypropyl)triméthoxysilane or EPTMS).

or X is Cl; L is CH₂CH₂CH₂ and R is CH3 (compound named 3-Chloropropyltriméthoxysilane or CPTMS).

An organosilane compound in the context of the present disclosure is 3-aminopropyl-trimethoxy-silane (APTMS).

A bifunctional organic binder is present in the activated solution in a quantity generally between 10⁻⁵ M and 10⁻¹ M, or between 10⁻⁴ M and 10⁻² M, or between 5×10⁻⁴ M and 5×10⁻³ M.

According to a particular feature of the disclosure, the activation solution is free of compound comprising at least two glycidile functions or of a compound comprising at least two isocyanate functions.

The solvent system of the solution according to the present disclosure must be suitable for solubilizing the activator and the binder defined above.

The solvent system may consist of one or more solvents selected from the group consisting of N-methylpyrrolidinone (NMP), dimethylsulphoxide (DMSO), alcohols, ethyleneglycol ethers such as for example monoethyl-diethyleneglycol, propyleneglycol ethers, dioxane and toluene.

In general, the solvent system advantageously consists of a mixture of a solvent suitable for solubilising the palladium complex in combination with a solvent such as an ethyleneglycol ether or a propyleneglycol ether.

A particularly preferred solvent solution in the context of the present disclosure, due to its very low toxicity, consists of a mixture of N methylpyrrolidinone (NMP) and monoethyl ether of diethyleneglycol. These compounds can be used in a volume ratio between 1:200 and 1:5, or about 1:10.

An activation solution in the context of the present disclosure contains:
(A) An activator consisting of one or more palladium complexes selected from the group consisting of:
   (1) Complexes having the formula (I), where:
      (a) R1 is H, R2 is CH2CH2NH2 and X is Cl, a complex named (diethylenetriamine)(dichloro)palladate(II);
      (b) R1 and R2 are identical and are CH2CH2OH and X is Cl, a complex named (N,N′-bis(2-hydroxyethyl)ethylenediamine)-(dichloro)palladate(II);
   (2) Complexes having the formula (IIa) where:
      (a) R1 is H, R2 is CH2CH2NH2 and Y is two Cl, a complex named trans-bis(diethylenetriamine)palladate(II);
   (3) Complexes having the formula (IIb) where:
      (a) R1 is H, R2 is CH2CH2NH2 and Y is two Cl, a complex named cis-bis(diethylenetriamine)palladate(II);
         in a concentration of 5×10−5 M to 5×10−4 M.
(B) A binder consisting of one or more organosilane compounds selected from the group consisting of compounds having formula (Va) where: X is NH₂ and
L is CH₂CH₂CH₂— and R is CH₃ (APTMS);
or L is CH₂CH₂CH₂— and R is CH₃CH₂(APTES);
or L is CH₂CH₂NHCH₂CH₂ and R is CH₃ (DATMS ou DAMO);
X is SH; L is CH₂CH₂CH₂— and R is CH2CH₃ (MPTES);
or X is C6H5N; L is CH₂CH₂— and R is CH2CH₃ (PETES);
or X is CHCH2O; L is CH₂CH₂CH₂ and R is CH₃ (EPTMS);
   or X is Cl; L is CH₂CH₂CH₂ and R is CH3 (CPTMS);
   L is CH2CH2CH2- and R is CH3, a compound named (3 aminopropyl)-trimethoxy-silane or APTMS;
   L is CH2CH2CH2- and R is CH3, a compound named (3 aminopropyl)-triethoxy-silane or APTES;
   L is CH2CH2NHCH2CH2 and R is CH3, acompound named [3-(2-aminoéthyl)aminopropyl]trimethoxy-silane or DATMS or DAMO;
   in a concentration between 10−3 M and 10−2 M.

In some embodiments, methods of preparing the conformal layer 108 by activating a semiconductor substrate 102 with a solution in preparation for subsequent coating by a metal layer deposition technique including those disclosed in French Patent Application No. 09-56800 filed Sep. 30, 2009, which is hereby incorporated herein by reference in its entirety for all purposes.

FIG. 2C shows a conductive layer 110 being formed around the perimeter of the photovoltaic cell 100. In one instance, formation of the conductive layer 110 may be substantially similar to that of the conformal layer 108. The conductive layer 110 may be gold, copper, aluminum or alloys thereof, among others. In some embodiments, the conductive layer 110 may be other suitable types of material having enhanced electrical conductivity. In one example, the conductive layer 110 may be formed by electroplating (e.g., light-induced plating). Plating techniques may be utilized because the front and back sides of the photovoltaic cell 100 can have substantially similar electrical potentials due to shorting of the conformal layer 108. In some instances, the conductive layer 110 may be formed by light-assisted electroplating or electroless plating, among other deposition methods.

FIG. 2D shows a pattern 114 being formed over the conductive layer 110. In one embodiment, the pattern 114 may be screen printed onto the photovoltaic cell 100 using chemical etchable photoresist onto a front side to define a collector or metal contact pattern 114. In some embodiments, other suitable photolithographic printing techniques may be incorporated for forming the pattern 114. In other instances, the pattern 114 may be formed by electron-beam or other suitable lithographic printing processes. In some aspect of the present disclosure, the pattern 114 may be transferred to the underlying layers and facilitate in the formation of the interconnects.

In one embodiment, the pattern 114 may include relatively narrow metal tracks whereby up to about 50% narrower metal lines may be produced in comparison to currently provided metal tracks. In other words, narrower linewidths may be produced by the pattern 114. Narrower metal line patterns 114 may be possible due to the presence of conformal layer 108, which can allow electrons to readily flow among any adjacent neighboring metal contact 110A. In some instances, up to 50% narrower metal tracks may produce photovoltaic cells 100 with conversion efficiency in the range of from about 16% to about 18%, or in some cases, in the range of from about 16.6% to about 17.2%.

FIG. 2E shows portions of the conductive layer 110 being etched (e.g., removed) to produce a patterned collector metal 110A. In this instance, the pattern 114 may be used for facilitating the removal of some portions of the conductive layer 110, while protecting certain portions of the conductive layer 110 in preventing its removal. The etching or removal process of the conductive layer 110 may be carried out using wet etch and/or dry etch chemistries via suitable etching techniques. In one instance, the photovoltaic cell 100 may be subjected to an over-etch of about 100% to produce metal contacts 110A with vertical sidewalls as shown in FIG. 2E. In other instances, the metal contacts 110A need not have vertical sidewalls. This will be discussed in further detail below. Also, in one instance, the etching process may be capable of removing only the conductive layer 110 without damaging or removing any of the underlying layers (e.g., conformal layer 108, p-n junction 104, n+ diffused layer 106). In other instances, the etching process may simultaneously remove both the conductive layer 110 and the conformal layer 108.

Furthermore, in addition to the top side of the conductive layer 110 being etched to produce a patterned collector metal 110A, the sidewalls of the photovoltaic cell 100 may also be etched or removed away thereby disrupting the conformity of the conductive layer 110. The etching of the top side and the sidewalls of the conductive layer 110 may be carried out in separate steps or simultaneously. For example, the bottom side of the conductive layer 110B (e.g., back side metal contact) may be protected from the etching process by a covering layer such as the likes of photoresist, silicon nitride or silicon dioxide, among other protective materials.

FIG. 2F shows the sidewalls of the conformal layer 108 being etched via substantially similar etching processes as those described above. In one embodiment, removal of the conformal layer 108 on the sidewalls can ensure that the front and back sides of the photovoltaic cell 100 are no longer in electrical contact. In other words, the top side metal contacts 110A and the back side metal contacts 110B will not short-circuit. Furthermore, removal of the conformal layer 108 from the sidewalls ensures that the interconnects (e.g., conformal layer 108, p-n junction 104, n+ diffused layer 106) will not short-circuit at the edges of the photovoltaic cell 100.

FIG. 2G shows the pattern 114 being removed by suitable chemical processes. In one example, the pattern 114 is a chemical etch photoresist that may be removed by a wet chemical solvent bath. In other instances, the pattern 114 may be removed by suitable dry etch and/or wet etch chemistries, among other techniques. After the pattern 114 has been removed, the metal contacts 110A remain on the top surface of the photovoltaic cell 100 maintaining the layout of the pattern 114. As shown in FIG. 2G, the photovoltaic cell 100 maintains a conformal surface of metallic shunt. In other words, the conformal layer 108 underneath the metal contacts 110A is able to electrically couple neighboring metal contacts 110A to each other. The continuous (e.g., conformal coverage) of the conductive conformal layer 108 may help to facilitate the energy conversion process by allowing electrons to readily flow to any of the adjacent metal contacts 110A without substantial electrical impedance.

In another embodiment, the conformal layer 108 underneath the metal contacts 110A may be removed. This will become more apparent in subsequent figures and discussion. Removal of the underlying conformal layer 108 may be necessary if the transparency of the conformal layer 108 is poor and does not permit external radiation from passing through. In other words, portions of the conformal layer 108 may be removed to permit external radiation from entering the interconnects including the likes of the p-n junction 104, the n+ diffused layer 106 and the substrate 102, among others.

FIG. 2H shows a covering layer 112 being deposited on the top side and sidewalls of the photovoltaic cell 100. In some instances, the covering layer 112 may sometimes be referred to as an anti-reflective layer. In other instances, the cover layer 112 may also be a protective layer being fabricated from a material including silicon dioxide, silicon nitride, among others. The covering layer 112 may facilitate in directing external radiation to the underlying layers to enhance the energy conversion process. In other words, the covering layer 112 may help to direct more sunlight to the interconnects for the energy conversion process.

In one instance, deposition of the covering layer 112 may be carried out at a sufficiently high temperature to ensure that an ohmic contact may be formed between the metal contacts 110A, the conformal layer 108 and the underlying layers (e.g., conformal layer 108, p-n junction 104, n+ diffused layer 106, substrate 102). In other instances, deposition of the covering layer 112 may be carried out at a temperature sufficiently high to ensure that an ohmic contact may be formed between the metal contacts 110A, the conformal layer 108 and the interconnects. In some examples, a separate annealing step may be carried out at the ohmic temperature of the material used in producing the conformal layer 108. In other words, if the conformal layer 108 is nickel, the annealing step may be carried out at a temperature that is sufficiently high to ensure a good ohmic contact is produced between the nickel and the underlying silicon substrate 102.

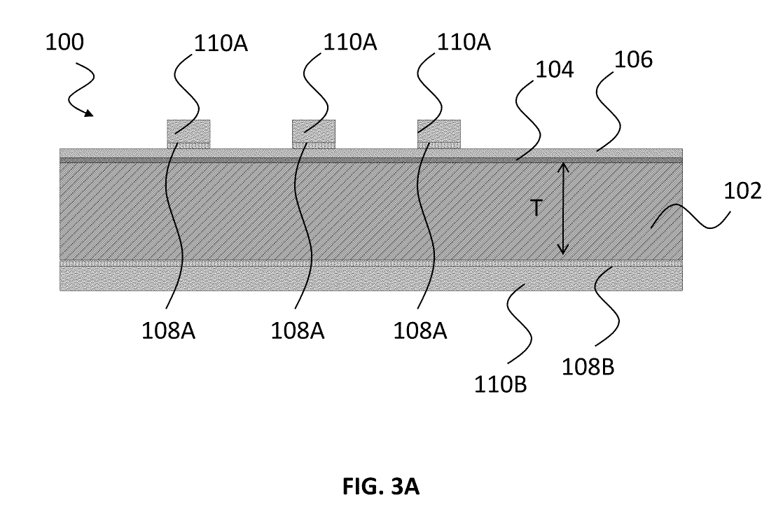

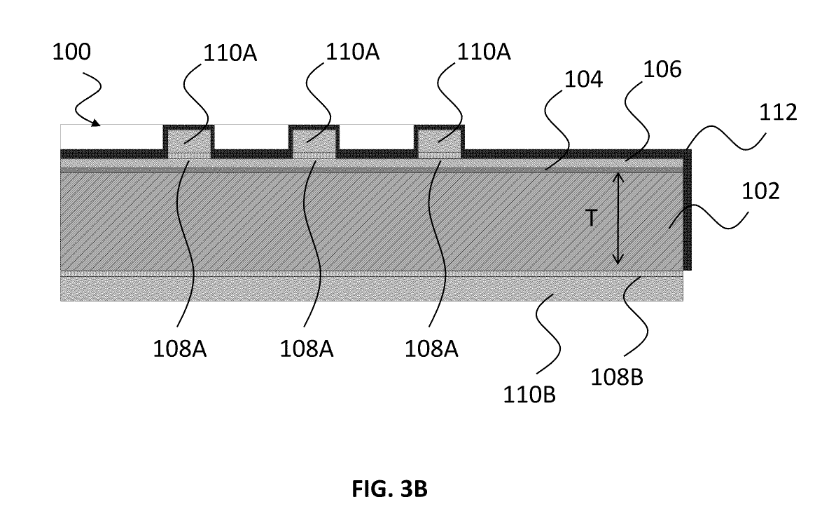

Reference is now made to FIGS. 3A-3B illustrating portions of a process flow of fabricating a photovoltaic cell 100 according to another embodiment of the present disclosure.

FIG. 3A shows the conformal layer 108 underneath the metal contacts 110A being removed after following the steps of FIGS. 2A-2G as discussed above. In one instance, the conformal layer 108 may be removed using suitable dry etch and/or wet etch semiconductor processes. As discussed above, portions of the conformal layer 108 between the top side metal contacts 110A may be removed when, for example, the transparency of the conformal layer 108 may be poor, such that the amount of light passing through to the interconnect and/or the substrate 102 may not be sufficient for the energy conversion process. In addition, removal of conformal layer 108 can occur since each top metal contact 110A may now electrically insulated from neighboring metal contacts 110A. As such, electron flow may take place through the underlying interconnects.

FIG. 3B shows a covering layer 112 being deposited on the top side and sidewalls of the photovoltaic cell 100 similar to that of FIG. 2H. As discussed above, the covering layer 112 not only protects the underlying features (e.g., interconnects) but may also increase the amount of sunlight being directed to the photovoltaic cell 100 thereby enhancing the energy conversion process.

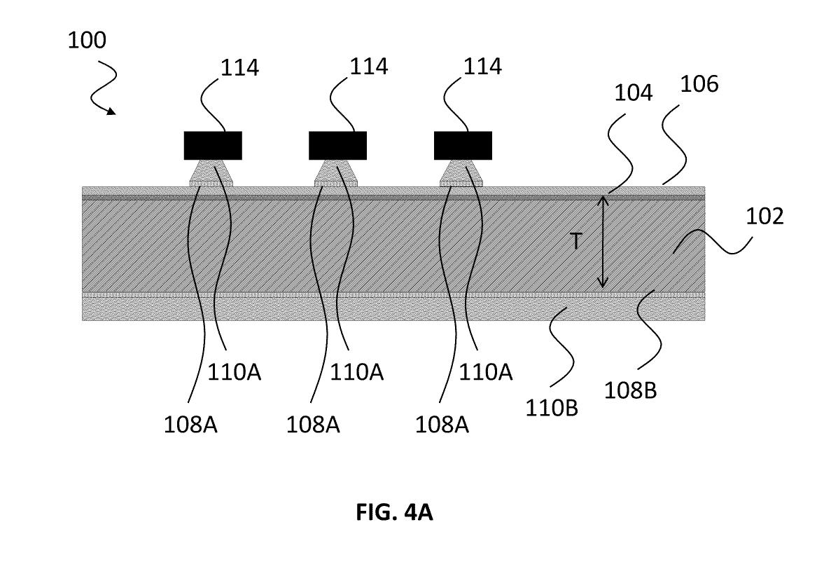

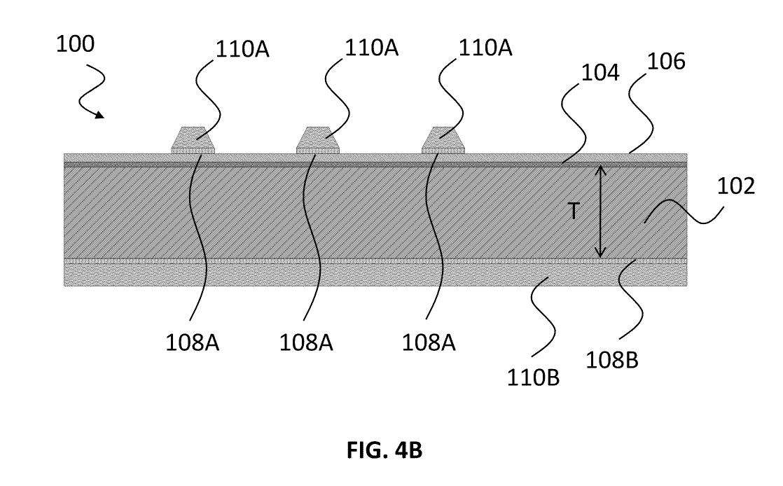

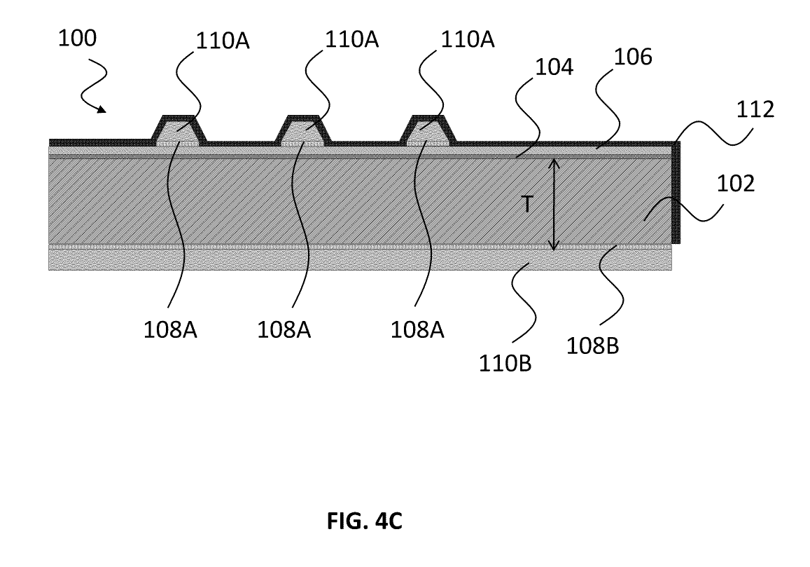

Reference is now made to FIGS. 4A-4C illustrating portions of a process flow of fabricating a photovoltaic cell 100 according to yet another embodiment of the present disclosure.

FIG. 4A shows the conductive layer 110 being removed after following the steps of FIGS. 2A-2D as discussed above using the pattern 114 as a mask. In this instance, over-etching of the conductive layer 110 may result in forming top side metal contacts 110A having tapered profiles as shown in FIG. 4A. One of the benefits of having the tapered profile may the ability of the tapered profile to increase the amount of sunlight being directed to the photovoltaic cell 100 thereby enhancing the energy conversion process. In one example, the conductive layer 110 may be over-etched by immersing the wafer in a chemical solution for an extended period of time. In these instances, the over-etch may be about 100% or in any other amount as necessary to produce the tapered or undercut profile. In this example, the underlying conformal layer 108 may also be etched at the same time.

FIG. 4B shows removal of the chemical photoresist pattern 114 similar to that of FIG. 2G. Like above, the pattern 114 may be removed using dry etch and/or wet etch semiconductor processes.

FIG. 4C shows a covering layer 112 being deposited on the top side and sidewalls of the photovoltaic cell 100 similar to that of FIGS. 2H and 3B. Like above, the covering layer 112 may be conformally deposited on the top surface and the sidewalls of the photovoltaic cell 100. As discussed, the covering layer 112 not only protects the underlying features (e.g., interconnects) but may also increase the amount of sunlight being directed to the photovoltaic cell 100 thereby enhancing the energy conversion process.

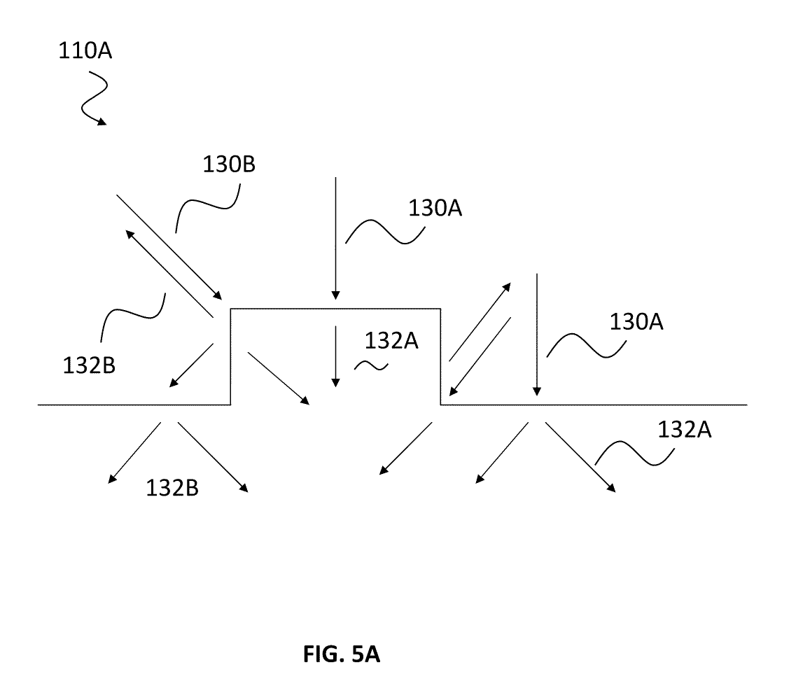

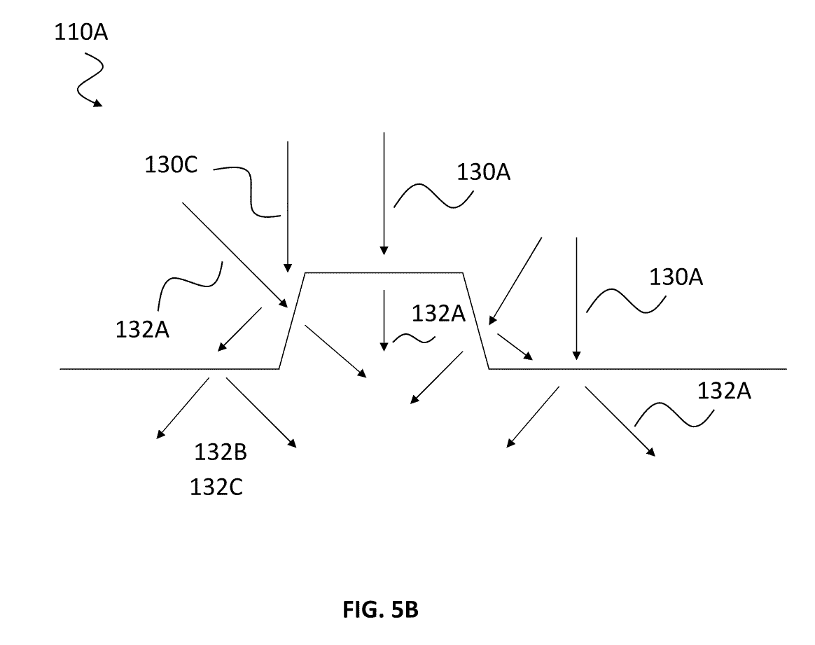

Reference is now made to FIGS. 5A-5B illustrating metal contacts 110A having vertical sidewalls (FIG. 5A) as shown in FIGS. 2G and 3A versus metal contacts 110A having tapered sidewalls (FIG. 5B) as shown in FIG. 4B.

In comparing the metal contacts 110A of FIGS. 5A-5B, photovoltaic cells 100 having tapered sidewalls (FIG. 5B) are capable of receiving a greater percentage of the external radiation 130 (e.g., sunlight) entering the cell 100 than photovoltaic cells 100 having vertical sidewalls (FIG. 5A). The external radiation 130 may enter the cells 100 at various angles and be received by the interconnects and the substrate 102 for the energy conversion process. The type of external radiation that may be received by the photovoltaic cell 100 includes diffuse irradiation and direct normal irradiation, among others. As used herein, diffuse irradiation refers to solar radiation that reaches the earth's surface indirectly from the sun (e.g., is first scattered by clouds, water and dust particles), while direct normal irradiation refers to solar radiation that is incident on the earth coming directly from the sun (e.g., no scattering).

In FIG. 5A, external radiation that enters, for example, at substantially 90 degree (e.g., perpendicular) 130A may be received by the metal contact 110A as shown by arrows 132A. However, certain portions of external radiation that enter at an angle 130B may be reflected by the straight, vertical sidewall such that the external radiation does not enter the metal contact 110A as shown by arrows 132B, while certain portions may be received within as shown by arrows 132B.

In contrast, in FIG. 5B, external radiation that enters, for example, at substantially 90 degree (e.g., perpendicular) 130A may be received by the metal contact 110A as shown by arrows 132A. Furthermore, a majority of external radiation that enters at an angle 130B may also enter the metal contact 110A as shown by arrows 132B due to the tapered profile, which is capable of directing the light to the interconnects and the substrate 102 of the photovoltaic cell 100. In some instances, external radiation that makes contact with the edge of the tapered profile as shown by arrows 130C may also be directed by the tapered profile into the metal contact 132C.

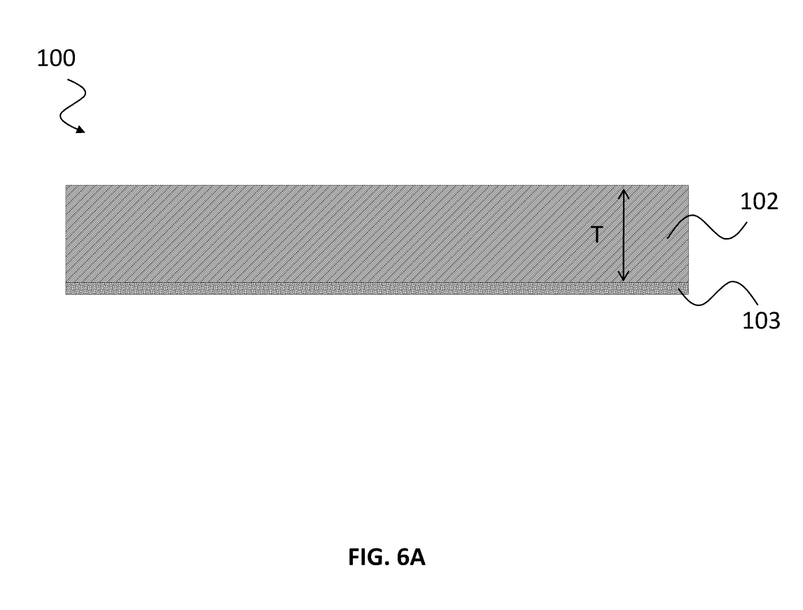

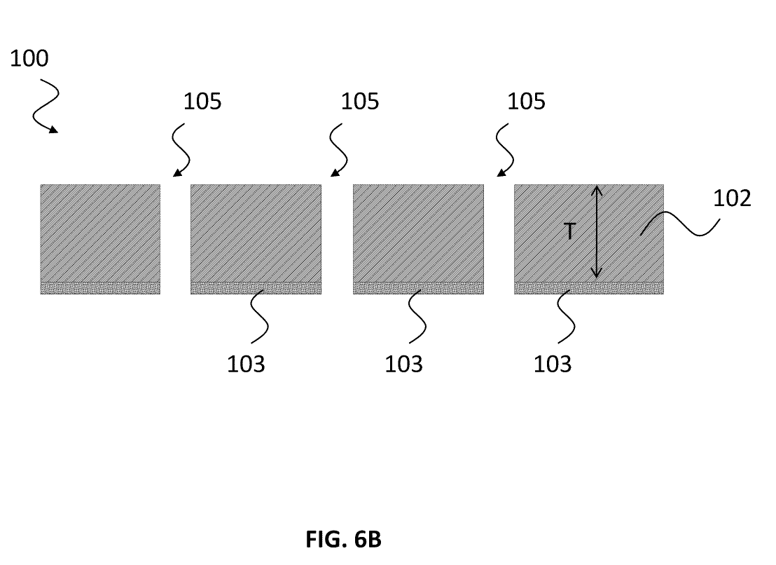

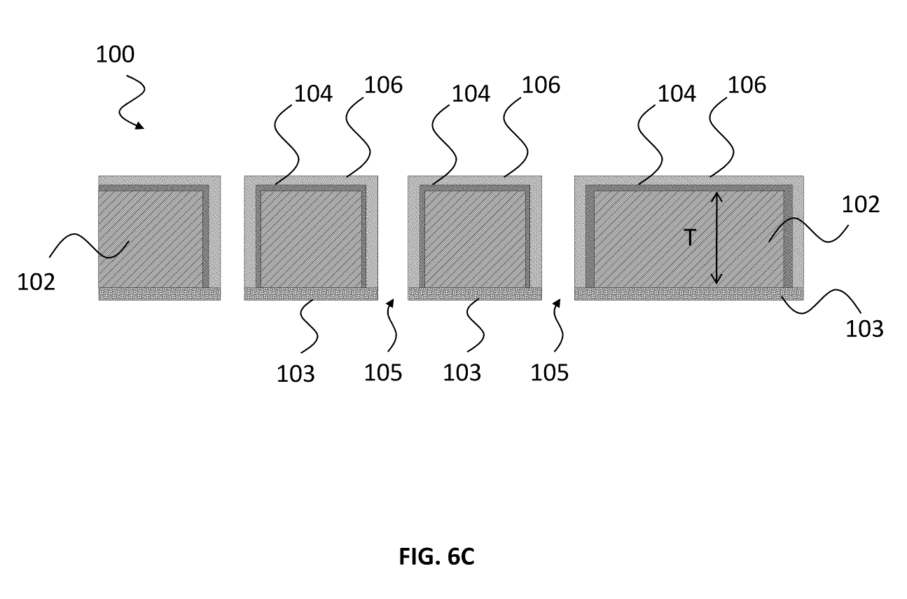

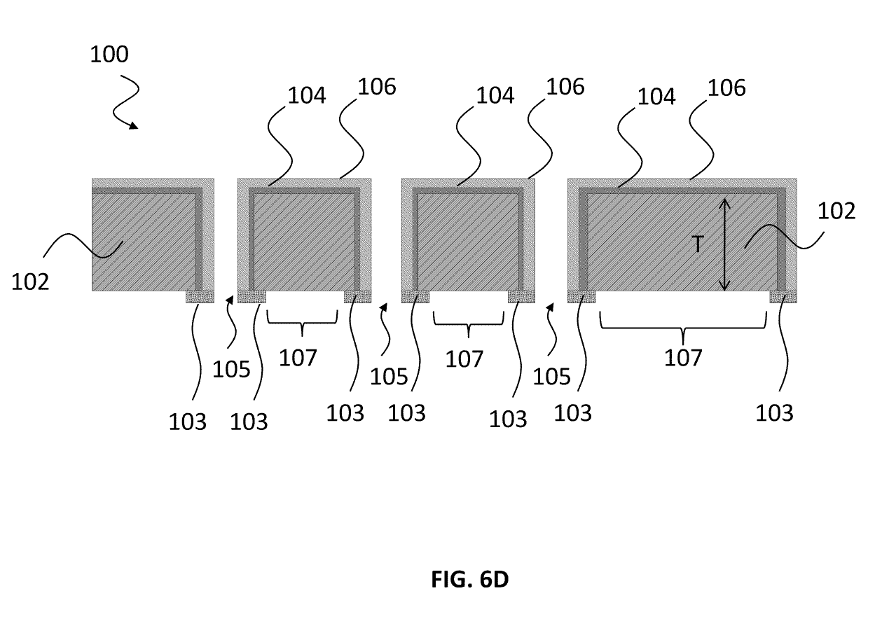

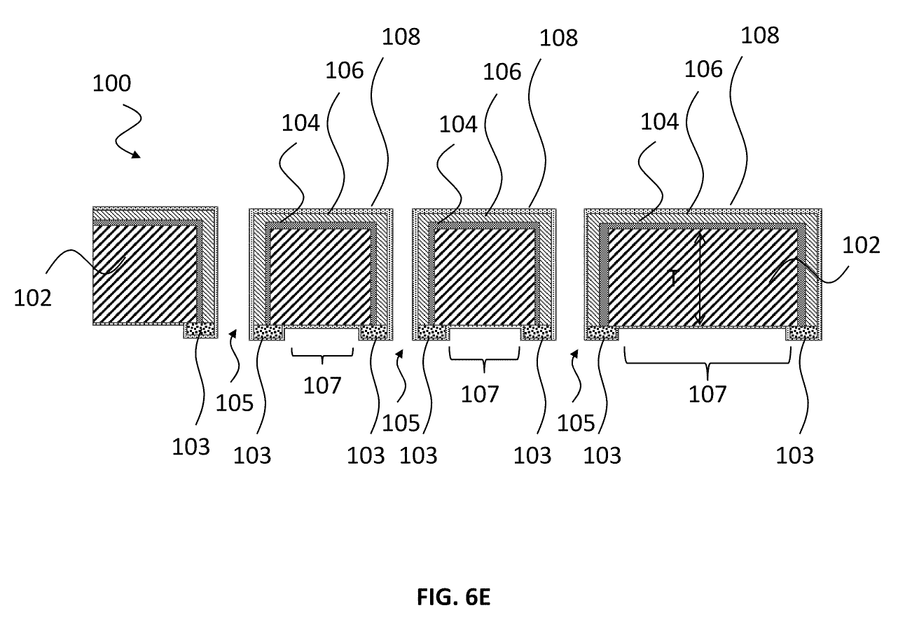

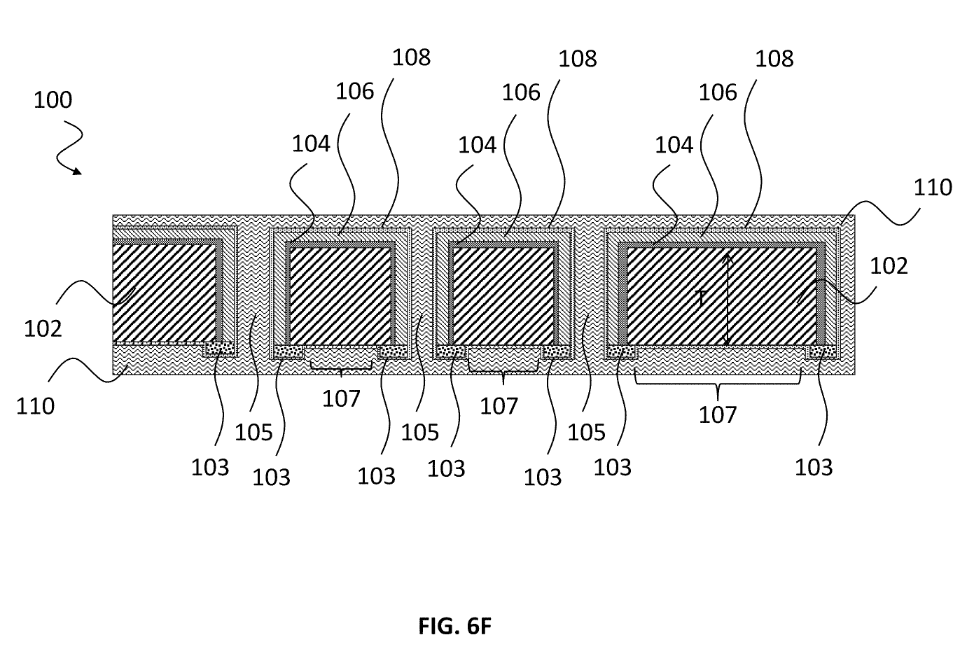

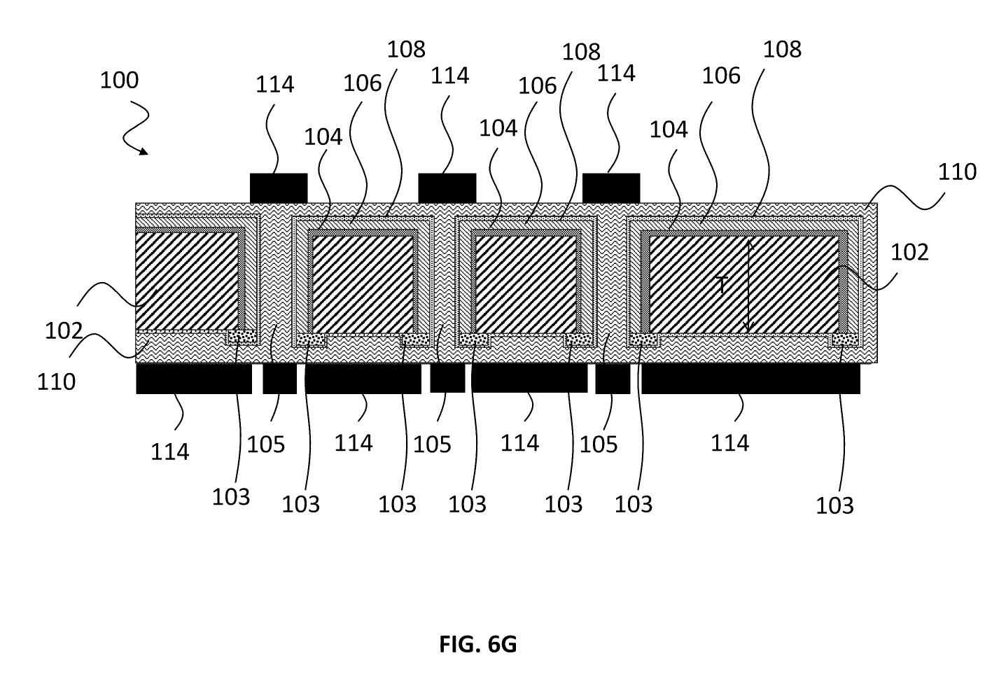

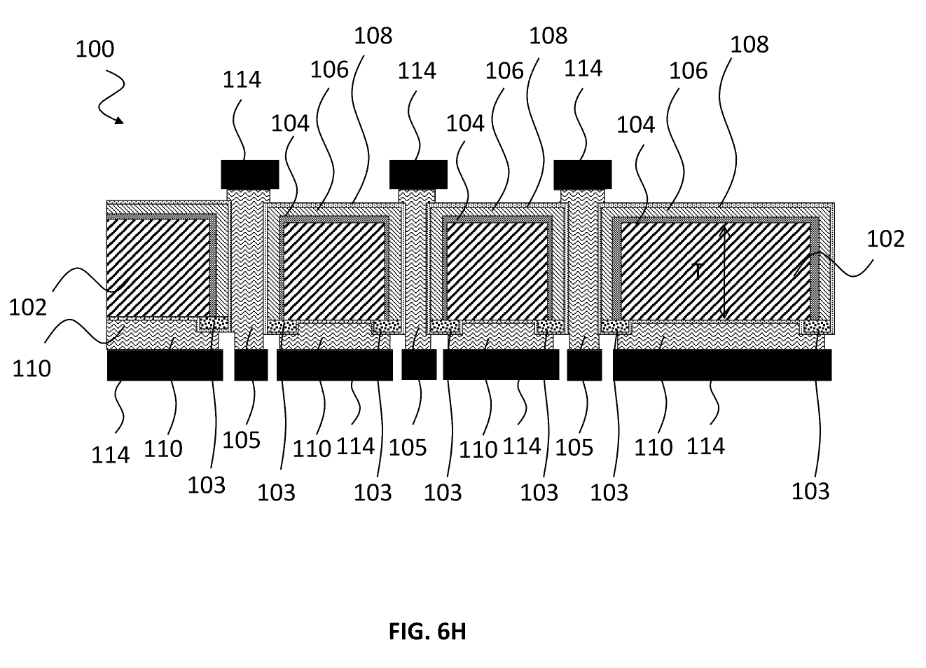

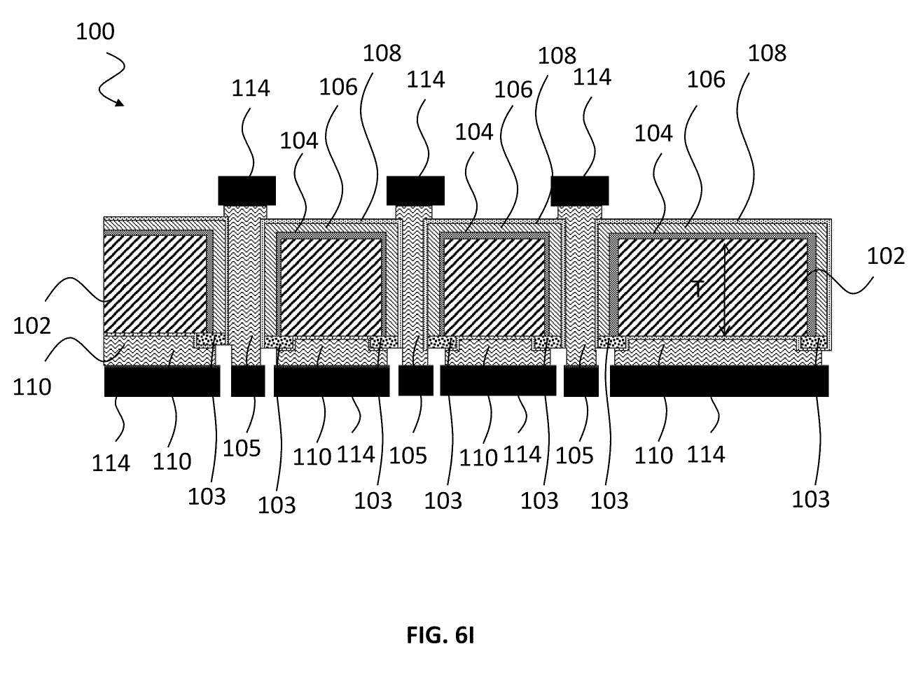

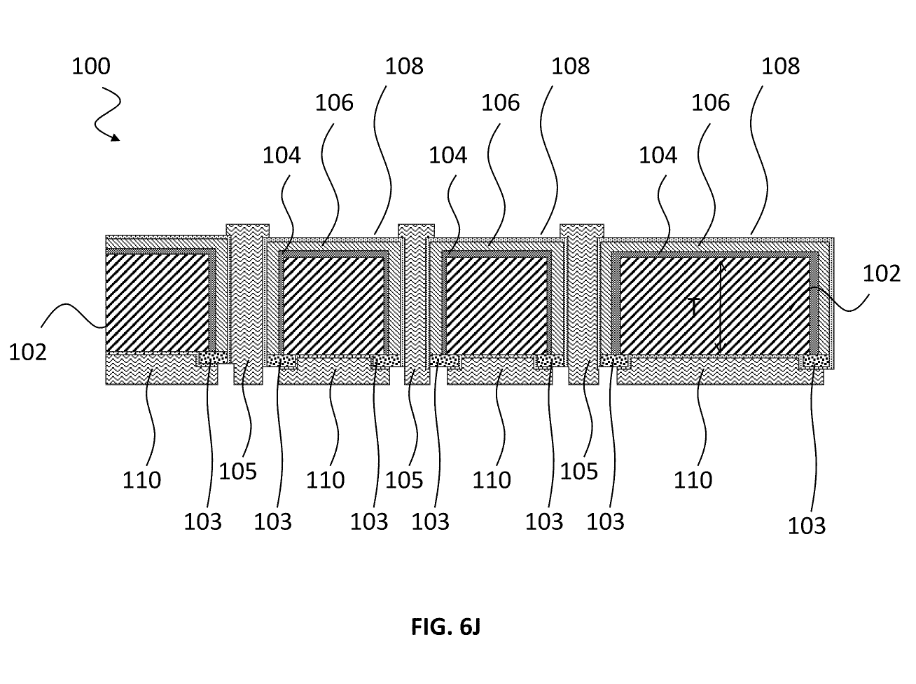

Reference is now made to FIGS. 6A-6J illustrating a process flow for fabricating a photovoltaic cell 100 according to another embodiment of the present disclosure. This process flow may sometimes be referred to as a metal wrap-through process and can be implemented to enhance energy conversion of the photovoltaic cell by allowing narrower metal stacks to be formed on the photovoltaic cell 100.

FIG. 6A shows a photovoltaic cell 100 having a substrate 102 with material property and thickness (T) similar to those described above. In this embodiment, the substrate 102 may be a textured bare silicon, whereby texturing may be carried out by immersing the bare silicon in an etching solution of water, hydrofluoric acid, nitric acid, or mixtures thereof. The bare silicon may also be textured in other suitable solutions and in combination with elevated or reduced temperatures known in the art. A protective oxide layer 103 may be formed about a back side of the substrate 102 by suitable diffusion techniques known in the art. In the alternative, other types of protective materials including the likes of silicon nitride and spin-on-glass, among others, may also be incorporated. The protective oxide layer 103, in this example, may function as a mask in allowing additional processes to be selectively carried out on certain portions of the substrate 102 while protecting others. This will become more apparent in subsequent figures and discussion.

FIG. 6B shows a plurality of apertures 105 being formed by, for example, laser drilling (e.g., laser ablation) through the substrate 102 and the oxide layer 103. The drilling can be carried out from the front side of the substrate 102 through the back side of the oxide layer 103. In some instances, the drilling process may be followed by a wet etch process (e.g., NaOH solution) for removing any debris that may remain during laser ablation. The wet etch may also facilitate the removal of any artifacts, defects and/or residues that may remain about the substrate 102, the aperture 105 and/or the oxide layer 103. Although a combination of laser drilling/wet etch process is disclosed, it should be appreciated that other suitable processes may be incorporated including suitable dry etch and/or wet etch processes known in the art. Formation of the apertures 105 may facilitate the formation of metal contact about the back side of the photovoltaic cell 100 by allowing metal contacts to be formed within the apertures 105. In other words, metal contacts that may normally be on the front side of the photovoltaic cell 100 may be “wrapped-through” (e.g., pulled, connected) to the back side via the apertures 105. The ability to allow metal contacts to wrap-through between the front side and the back side may reduce the footprint of a photovoltaic cell 100 as metal contacts may be placed closer to each other.

FIG. 6C shows a p-n junction 104 and a n+ diffused layer 106 formed by introducing dopants via suitable furnace diffusion processes known in the art. Alternatively, the p-n junction 104 and the n+ diffused layer 106 may be formed by ion implantation followed by rapid thermal annealing. The purpose and function of the p-n junction 104 and the n+ diffused layer 106 are similar to those discussed above. Specifically, the p-n junction and the n+ diffused layer 106 may be part of the interconnects to facilitate energy conversion of the photovoltaic cell 100.

FIG. 6D shows openings 107 formed on the backside of the oxide layer 103 by patterning and etching with suitable wet etch and/or dry etch processes known in the art. The selectively-etched openings 107 allow the underlying substrate 102 to be exposed to subsequent processing steps. Specifically, the openings 107 may facilitate energy conversion of the photovoltaic cell 100 by allowing a conductive material to be coupled substantially adjacent the substrate 102. In doing so, the flow path that electrons have to travel for the recombination process may be minimized. In addition, electrons may readily flow to neighboring metal contacts in carrying out the energy conversion process.

FIG. 6E shows a substantially conformal layer 108 being formed about the periphery of the p-n junction 104 and the n+ diffused layer 106, including conformal coverage of the oxide layer 103, the apertures 105 and the openings 107. The conformal layer 108 may be formed via substantially similar materials and/or processes discussed above. Specifically, the conformal layer 108 may be a nickel-boron alloy formed using the immersion processes discussed above. The purpose and function of the conformal layer 108 are generally similar to those discussed above. Specifically, the conformal layer 108 may be substantially thin, conformal and transparent so as to enhance energy conversion of the photovoltaic cell 100.

FIG. 6F shows a conductive layer 110 being formed about the periphery of the conformal layer 108, including filling of the apertures 105 and the openings 107. In one embodiment, the conductive layer 110 may be conformally formed using materials and/or processes that are substantially similar to that of the conformal layer 108. The purpose and function of the conductive layer 110 may be substantially similar to those discussed above. Specifically, the apertures 105, after having been filled with a conductive material such as copper or gold, may facilitate wrap-through of metal contacts from about the front side of the photovoltaic cell 100 to about the back side of the photovoltaic cell 100 with the copper or gold providing the electrical conductivity and serving as an electrode for the photovoltaic cell 100.

FIG. 6G shows a pattern 114 being formed about the front and back sides of the photovoltaic cell 100. In an embodiment a n+ collector electrode pattern may be defined on the front side and an inter-digitated pattern of fingers may be provided on the back side. In this instance, the pattern 114 may be formed by applying a chemically etchable material such as a photoresist about the photovoltaic cell 100 and screen-printing the same. The purpose and function of the pattern 114 may be similar to those discussed above. Specifically, the pattern 114 functions to provide a mask in helping to define the electrical circuits and/or layouts for the photovoltaic cell 100 (e.g., collector electrode and inter-digitated patterns). The electrical circuits and/or layouts may be related to the interconnects in carrying out the electrical commands/instructions. In some instances, the electrical circuits and/or layouts may also be related to the electrode and inter-digitated patterns.

FIG. 6H shows an etching process being carried out on the photovoltaic cell 100 using pattern 114 as a mask substantially similar to that discussed above. Specifically, the etching process may involve etching the primary conductors in accordance with the pattern 114 using a wet bath etch process. The etching process may also incorporate any of the wet etch and/or dry etch process known in the art. Specifically, the etching helps to remove portions of the conductive layer 110 in order to prevent shorting of the collector metal contacts (e.g., backside metal contacts 110 and the conductive metal within the apertures 105). The etching may also help to remove the conductive material from the side walls of the photovoltaic cell 100. The metal contacts being formed by the conductive layer 110 may be capable of functioning as electrodes for the photovoltaic cell 100. In some embodiments, the etched conductive layer 110 may have vertical or tapered wall profiles similar to those shown in FIGS. 5A-5B using extended wet etch (e.g., 100% over-etch) and/or dry etch processes or other suitable removal processes known in the art. In this example, over-etching may occur without removing the underlying nickel conformal layer 108.

FIG. 6I shows an additional etching process being carried out on the photovoltaic cell 100 with the removal of the underlying nickel-boron alloy conformal layer 108. As discussed above, the etching process may be necessary to prevent shorting of the metal contacts and by separating backside metal contacts 110 from the conductive metal within the apertures 105. In some instances, the processing steps of FIGS. 6H and 6I may be integrated as a single step.

FIG. 6J shows a removal process of the chemical resists for forming the pattern 114 from both the front and back sides of the photovoltaic cell 100 using a wet solvent bath. In some instances, the chemical resists for forming the pattern 114 may be removed by other suitable removal processes known in the art. Once removed, the photovoltaic cell 100, according to one embodiment, may be completed and used for the energy conversion process for converting solar energy to electrical energy similar to that previously discussed. Specifically, the conductive material within the apertures 105 may function as one set of electrodes (e.g., collector electrode pattern) while the back side metal contacts 110 adjacent the substrate 100 and the protective oxide layer 103 may function as another set of electrodes (e.g., inter-digitated pattern). Once the metal wrap-through photovoltaic cell 100 has been completed, a protective layer (not shown) such as silicon nitride may be formed about a top surface of the photovoltaic cell 100 for protecting and/or covering the underlying layers and materials since both electrodes are now on the back side of the photovoltaic cell 100. In some instances, the processing steps of FIGS. 6I and 6J may be integrated as a single step. In other instances, the processing steps of FIGS. 6H-6J may be integrated as a single step.

### Applications

The photovoltaic cell made in accordance with an embodiment of the present disclosure includes a substrate whereby at least one interconnect may be formed over the substrate to facilitate energy conversion of the photovoltaic cell. In an embodiment, a conformal layer may be deposited over the interconnects to permit external radiation to pass through to the interconnects so as to enhance the efficiency of energy conversion by at least about 25% as measured at standard test condition. The conformal layer, in this embodiment, may be provided with a thickness of up to about 100 nm.

In another embodiment, the interconnects of the photovoltaic cell may have tapered profile as to facilitate collection of diffused external radiation. In some instances, the tapered profile may facilitate in diverting the diffused external radiation to the interconnects for enhancing energy conversion of the photovoltaic cell.

In a further embodiment, the photovoltaic cell includes a semiconductor substrate having at least one interconnects, and a first conductive material about the perimeter of the semiconductor substrate. The first conductive material, in one embodiment, may be substantially transparent and/or conformal. A second conductive layer may be provide over the first conductive layer whereby the thickness of the second conductive layer can be greater than the thickness of the first conductive layer. A pattern may also be provided within the second conductive layer. In one embodiment, the pattern within the second conductive layer may produce at least one metal contact having an undercut profile. An insulating layer may also be provided over the second conductive layer thereby producing the photovoltaic cell.

In some embodiments, a plurality of photovoltaic cells may be interconnected in series or in parallel to produce solar panels and/or solar modules, the modules having conversion efficiency similar to those of individual photovoltaic cells. Additional resistors, capacitors, converters, among other electrical and/or mechanical devices, may be incorporated as known by one skilled in the art. In other embodiments, the photovoltaic cells may be coupled to form photovoltaic arrays. In yet other embodiments, the photovoltaic cells may be used for powering devices including the likes of multi-touch screens, flat panel displays, touch screens, to name a few. The flat panel displays and touch screens may be used in consumer products, mobile devices and medical devices, among others. In other instances, the solar modules and/or photovoltaic arrays may be used for supplying electrical power to signages and street lights with or without the use of additional external power supplies (e.g., batteries). In some embodiments, the solar module and/or solar array may serve as to bridge or supplement consumer electronics products and traditional power source such as a battery and electrical cable outlet.

While the invention has been described in connection with the specific embodiments thereof, it will be understood that it is capable of further modification. Furthermore, this application is intended to cover any variations, uses, or adaptations of the invention, including such departures from the present disclosure as come within known or customary practice in the art to which the invention pertains, and as fall within the scope of the appended claims.

What is claimed is:

1. A photovoltaic cell comprising:
a substrate;
at least one interconnect formed over the substrate to facilitate energy conversion of the photovoltaic cell; and
a conformal layer deposited over the interconnect and having a thickness of up to about 100 nm, the conformal layer being designed to permit external radiation to pass through to the interconnect so as to enhance efficiency of energy conversion by at least about 25% as measured at standard test condition.

2. The photovoltaic cell of claim 1, wherein the interconnects have a tapered profile.

3. The photovoltaic cell of claim 2, wherein the tapered profile facilitates collection of diffused external radiation.

4. The photovoltaic cell of claim 2, wherein the tapered profile facilitates in diverting the diffused external radiation to the interconnects for enhancing energy conversion of the photovoltaic cell.

5. A photovoltaic cell comprising:
a substrate conditioned with a solution to permit the surface of the substrate to receive a conformal metal coating by electroless deposition; and
a nickel-boron layer provided on the substrate by electroless deposition, the nickel-boron layer being substantially conformal and having a thickness of up to about 100 nm, so as to enhance efficiency of energy conversion of external radiation directed through the layer and to the substrate.

6. The photovoltaic cell of claim 5, the nickel-boron layer capable of enhancing efficiency of energy conversion by at least about 25% as measured at standard test condition.

7. The photovoltaic cell of claim 5, further comprising at least one interconnect formed over the substrate to facilitate energy conversion of the photovoltaic cell.

8. The photovoltaic cell of claim 7, wherein the interconnects have a tapered profile to facilitate in collection of diffused external radiation.

9. The photovoltaic cell of claim 7, wherein the interconnects have a tapered profile to facilitate in diverting the diffused external radiation to the interconnects for enhancing energy conversion of the photovoltaic cell.

10. A method of manufacturing a photovoltaic cell comprising:
providing a solution designed to condition a substrate surface to receive a conformal metal coating by electroless deposition;
immersing a substrate into the solution; and
depositing on to the surface of the substrate a substantially conformal first conductive material.

11. The method of claim 10, wherein, in the step of depositing, the first conductive material is substantially transparent, and has a thickness of up to about 100 nm.

12. The method of claim 10, wherein, in the step of depositing, the first conductive material is nickel-boron.

13. The method of claim 10, wherein the first conductive material enhances the efficiency of energy conversion by at least about 25% as measured at standard test condition.

14. The method of claim 10, further comprising depositing a second conductive material on to first conductive material.

15. The method of claim 14, wherein the second conductive material is at least one of copper, gold, aluminum or alloys thereof.

16. The method of claim 10, further comprising providing at least one interconnect on the substrate to facilitate energy conversion of the photovoltaic cell.

17. The method of claim 16, wherein, in the step of providing, the interconnects have a tapered profile to facilitate in collection of diffused external radiation.

18. The method of claim 16, wherein, in the step of providing, the interconnects have a tapered profile to facilitate in diverting the diffused external radiation to the interconnects for enhancing energy conversion of the photovoltaic cell.

19. A solar module comprising at least one photovoltaic cell of claim 1.

20. An integrated circuit incorporating the photovoltaic cell of claim 1 for use in connection with one of a powering device, a multi-touch screen, a flat panel display, a touch screen, a mobile device, and a medical device.

21. An integrated circuit incorporating the photovoltaic cell of claim 1 for use in connection with supplying electrical power to signages, street lights or similar devices.

22. An integrated circuit incorporating the photovoltaic cell of claim 1 for use in connection as a bridge or supplement to traditional power source for consumer electronics products.

23. A photovoltaic cell comprising:
a substrate;
at least one interconnect formed over the top side of the substrate to facilitate energy conversion of the photovoltaic cell;
a conformal layer deposited over the interconnect and having a thickness of up to about 100 nm, the conformal layer being designed to permit external radiation to pass through to the interconnect so as to enhance efficiency of energy conversion by at least about 25% as measured at standard test condition; and
a passageway coupled to the conformal layer, the passageway extending from the top side of the substrate through to the back side of the substrate.
